(19) United States
(12) Patent Application Publication
(10) Pub. No.: US 2017/0218128 A1
(43) Pub. Date: Aug. 3, 2017

(54) Curable Silicone Resin Composition, Cured Object Obtained Therefrom, and Optical Semiconductor Device Formed Using Same

(71) Applicant: Central Glass Company, Limited, Ube-shi, Yamaguchi (JP)

(72) Inventors: Wataru KAWAI, Fujimi-shi, Saitama (JP); Katsuhiro AKIYAMA, Iruma-gun, Saitama (JP); Yu MATSUNO, Asaka-shi, Saitama (JP); Junya NAKATSUJI, Fujimino-shi, Saitama (JP); Makoto SEINO, Ube-shi, Yamaguchi (JP)

(21) Appl. No.: 15/328,067

(22) PCT Filed: Jul. 10, 2015
(86) PCT No.: PCT/JP2015/069877

§ 371 Date: Jan. 23, 2017

(30) Foreign Application Priority Data
Jul. 24, 2014 (JP) 2014-150494
Mar. 13, 2015 (JP) 2015-050137
Jun. 30, 2015 (JP) 2015-131140

(51) Int. Cl. C08G 77/04; C08G 77/08; C09J 183/04; C08K 5/3492; C08K 5/372; H01L 33/56; C08K 5/3435

(52) U.S. Cl. CPC C08G 77/04; H01L 33/56; C08G 77/08; C08K 5/3435; C08K 5/34924; C08K 5/372; C09J 183/04; H01L 2933/005; C08G 77/80

(57) ABSTRACT

A curable silicone resin composition according to the present invention includes at least the following components: (A) a silicone resin having a hydrogen atom bonded to silicon atom (as SiH group); (B) a silicone resin having a vinyl group bonded to silicon atom (as Si—CH═CH₂ group); and (C) a platinum catalyst, wherein the total amount of silanol (Si—OH) group in the components (A) and (B) is 0.5 to 5.0 mmol/g; and wherein the amount of platinum in the component (C) relative to the total mass of the components (A), (B) and (C) is 0.003 to 3.0 ppm in mass units. A cured product obtained by heating the composition is suitably usable as an encapsulant of an optical semiconductor device.

### FIELD OF THE INVENTION

The present invention relates to a curable silicone resin composition, which is suitably usable as a raw material for the formation of encapsulants of optical semiconductor elements such as light-emitting diodes. The present invention also relates a cured product of the composition and an optical semiconductor device using the composition or cured product.

### BACKGROUND ART

Cured products of epoxy resin compositions and silicone resin compositions are used as encapsulants of light-emitting devices using optical semiconductor elements such as light-emitting diodes (abbreviation: LED). These encapsulants are required to maintain transparency even under long-term exposure to high temperatures, i.e., show good heat resistant transparency.

In general, the cured products of the epoxy resin compositions are high in hardness and attain not only good handling property but also durability required for use as encapsulants of low-output white LED etc. Thus, the cured products of the epoxy resin compositions are widely used for low-output applications

There has recently been a tendency to increase the brightness and output performance of the LED. Under such circumstances, however, it is known that the cured products of the conventional transparent epoxy resin compositions cannot attain sufficient heat resistance for use as encapsulants of power semiconductor elements, high-brightness light-emitting elements (e.g. high-brightness LED for headlights of automotive vehicles or backlights of liquid crystal displays) and short-wavelength semiconductor lasers e.g. blue lasers and thereby cause current leakage, yellowing etc. due to high-temperature degradation.

In order to solve these problems, the cured products of the heat-resistant silicone resin compositions have recently been put into use as encapsulants of LED in place of the cured products of the epoxy resin compositions. For example, Patent Document 1 discloses, as a material for protection and encapsulation of an optical element or semiconductor element, an addition-curable silicone resin composition that utilizes addition (hydrosilylation) reaction between SiH group and alkenyl group.

### PRIOR ART DOCUMENTS

### Patent Documents

Patent Document 1: Japanese Laid-Open Patent Publication No. 2000-198930

### SUMMARY OF THE INVENTION

### Problems to be Solved by the Invention

Many of addition-curable silicone resin compositions contain platinum-group metal catalysts, particularly platinum catalysts, as curing catalysts. However, the silicone resin compositions containing the platinum catalysts may turn yellow under long-term exposure to high temperatures. The cured products of the silicone resin compositions containing the platinum catalysts thus face the problem of transparency deterioration under long-term exposure to high temperatures. With the recent development of high-brightness LED, there has been a demand to provide a silicone resin composition capable of forming a cured product that solves the above problem and shows sufficient transparency even under long-term exposure to high temperatures, i.e., good heat resistant transparency.

The present invention has been made in view of the foregoing. It is an object of the present invention to provide an addition-curable silicone resin composition capable of forming a cured product with good heat resistant transparency. It is also an object of the present invention to provide a cured product of the composition and an optical semiconductor device using the composition or cured product.

### Means for Solving the Problems

As a result of extensive researches, the present inventors have found that it is possible to achieve the above object by the use of a curable silicone resin composition containing at least: (A) a silicone resin having a hydrogen atom bonded to silicon atom (as SiH group) as represented by the following formula [1]; (B) a silicone resin having a vinyl group bonded to silicon atom (as Si—CH═CH₂ group) as represented by the following formula [2]; and (C) a platinum catalyst, wherein the total amount of silanol (Si—OH) group in the components (A) and (B) is 0.5 to 5.0 mmol/g; and wherein the amount of platinum atom in the component (C) relative to the total mass of the components (A), (B) and (C) is 0.003 to 3.0 ppm in mass units,

(H—SiR¹₂O_{1/2})ₐ(SiR²₂O_{2/2})_{b}(R³SiO_{3/2})_{c}(SiO_{4/2})_{d} [1]

where R¹ is each independently a C₁-C₃ alkyl group; two R¹ may be of the same kind or different kinds; R² is each independently a C₁-C₃ alkyl group; two R² may be of the same kind or different kinds; R³ is a C₁-C₃ alkyl group or C₆-C₁₀ aromatic hydrocarbon group; a, b and c are each independently a number greater than 0 and smaller than 1; d is a number greater than or equal to 0 and smaller than 1; a, b, c and d satisfy the condition of a+b+c+d=1; and each of oxygen atoms in structural units (SiR²₂O_{2/2}), (R³SiO_{3/2}) and (SiO_{4/2}) is a siloxane bond-forming oxygen atom or a silanol group-forming oxygen atom;

(CH₂═CH—SiR⁴₂O_{1/2})ₑ(SiR⁵₂O_{2/2})_{f}(R⁶SiO_{3/2})_{g}(SiO_{4/2})ₕ [2]

where R⁴ is each independently a C₁-C₃ alkyl group; two R⁴ may be of the same kind or different kinds; R⁵ is each independently a C₁-C₃ alkyl group; two R⁵ may be of the same kind or different kinds; R⁶ is a C₁-C₃ alkyl group or C₆-C₁₀ aromatic hydrocarbon group; e, f and g are each independently a number greater than 0 and smaller than 1; h is a number greater than or equal to 0 and smaller than 1; e, f g and h satisfy the condition of e+f+g+h=1; and each of oxygen atoms in structural units (SiR⁵₂O_{2/2}), (R⁶SiO_{3/2}) and (SiO_{4/2}) is a siloxane bond-forming oxygen atom or a silanol group-forming oxygen atom.

Namely, the present invention includes the following inventive aspects 1 to 15.

[Inventive Aspect 1]

A curable silicone resin composition comprising at least the following components:

(A) a silicone resin having a hydrogen atom bonded to silicon atom (as SiH group) as represented by the following formula [1];

(B) a silicone resin having a vinyl group bonded to silicon atom (as Si—CH═CH₂ group) as represented by the following formula [2]; and

(C) a platinum catalyst,

wherein the total amount of silanol (Si—OH) group in the components (A) and (B) is 0.5 to 5.0 mmol/g; and

wherein the amount of platinum in the component (C) relative to the total mass of the components (A), (B) and (C) is 0.003 to 3.0 ppm in mass units,

(H—SiR¹₂O_{1/2})ₐ(SiR²₂O_{2/2})_{b}(R³SiO_{3/2})ₑ(SiO_{4/2})_{d} [1]

where R¹ is each independently a C₁-C₃ alkyl group; two R¹ may be of the same kind or different kinds; R² is each independently a C₁-C₃ alkyl group; two R² may be of the same kind or different kinds; R³ is a C₁-C₃ alkyl group or C₆-C₁₀ aromatic hydrocarbon group; a, b and c are each independently a number greater than 0 and smaller than 1; d is a number greater than or equal to 0 and smaller than 1; a, b, c and d satisfy the condition of a+b+c+d=1; and each of oxygen atoms in structural units (SiR²₂O_{2/2}), (R³SiO_{3/2}) and (SiO_{4/2}) is a siloxane bond-forming oxygen atom or a silanol group-forming oxygen atom;

(CH₂═CH—SiR⁴₂O_{1/2})ₑ(SiR⁵₂O_{2/2})_{f}(R⁶SiO_{3/2})_{g}(SiO_{4/2})ₕ [2]

where R⁴ is each independently a C₁-C₃ alkyl group; two R⁴ may be of the same kind or different kinds; R⁵ is each independently a C₁-C₃ alkyl group; two R⁵ may be of the same kind or different kinds; R⁶ is a C₁-C₃ alkyl group or C₆-C₁₀ aromatic hydrocarbon group; e, f and g are each independently a number greater than 0 and smaller than 1; h is a number greater than or equal to 0 and smaller than 1; e, f g and h satisfy the condition of e+f+g+h=1; and each of oxygen atoms in structural units (SiR⁵₂O_{2/2}), (R⁶SiO_{3/2}) and (SiO_{4/2}) is a siloxane bond-forming oxygen atom or a silanol group-forming oxygen atom.

[Inventive Aspect 2]

The curable silicone resin composition according to Inventive Aspect 1,

wherein the ratio of a mole number of the hydrogen atom bonded to the silicon atom in the component (A) to a mole number of the vinyl group bonded to the silicon atom in the component (B) is in a range of 0.8:0.2 to 0.5:0.5.

[Inventive Aspect 3]

The curable silicone resin composition according to Inventive Aspect 1 or 2,

wherein, in the component (A), a, b, c and d satisfy the condition of a:b:c:d=0.05 to 0.40:0.10 to 0.80:0.10 to 0.80:0 to 0.70; and

wherein, in the component (B), e, f, g and h satisfy the condition of e:f:g:h=0.05 to 0.40:0.10 to 0.80:0.10 to 0.80:0 to 0.70.

[Inventive Aspect 4]

The curable silicone resin composition according to any one of Inventive Aspects 1 to 3,

wherein, in the component (A), a, b, c and d satisfy the condition of a:b:c:d=0.20 to 0.40:0.10 to 0.40:0.30 to 0.60:0.10 to 0.30; and

wherein, in the component (B), e, f, g and h satisfy the condition of e:f:g:h=0.20 to 0.40:0.10 to 0.40:0.30 to 0.60:0.10 to 0.30.

[Inventive Aspect 5]

The curable silicone resin composition according to Inventive Aspect 1 or 2,

wherein, in the component (A), a, b, c and d satisfy the condition of d=0 and a:b:c=0.05 to 0.40:0.10 to 0.80:0.10 to 0.80; and

wherein, in the component (B), e, f g and h satisfy the condition of h=0 and e:f:g=0.05 to 0.40:0.10 to 0.80:0.10 to 0.80.

[Inventive Aspect 6]

The curable silicone resin composition according to any one of Inventive Aspects 1 to 5, further comprising a curing retardant.

[Inventive Aspect 7]

The curable silicone resin composition according to any one of Inventive Aspects 1 to 6, further comprising an antioxidant or a light stabilizer.

[Inventive Aspect 8]

The curable silicone resin composition according to any one of Inventive Aspects 1 to 7, further comprising one or more kinds selected from the group consisting of a bonding aid, a phosphor and an inorganic particulate material.

[Inventive Aspect 9]

The curable silicone resin composition according to any one of Inventive Aspects 1 to 8, further comprising one or more kinds selected from the group consisting of a mold releasing agent, a resin modifying agent, a coloring agent, a diluent, an antimicrobial agent, a fungicide, a leveling agent and an anti-sagging agent.

[Inventive Aspect 10]

A cured product formed by curing the curable silicone resin composition according to any one of Inventive Aspects 1 to 9.

[Inventive Aspect 11]

An encapsulant comprising a cured product of the curable silicone resin composition according to any one of Inventive Aspects 1 to 9.

[Inventive Aspect 12]

A method for forming a cured product by curing the curable silicone resin composition according to any one of Inventive Aspects 1 to 9, comprising heating the curable silicone resin composition at 45° C. to 300° C.

[Inventive Aspect 13]

An optical semiconductor device comprising an optical semiconductor element encapsulated by a cured product of the curable silicone resin composition according to any one of Inventive Aspects 1 to 9.

[Inventive Aspect 14]

A semiconductor bonding material comprising a cured product of the curable silicone resin composition according to any one of Inventive Aspects 1 to 9.

[Inventive Aspect 15]

An optical semiconductor device comprising the semiconductor bonding material according to Inventive Aspect 14.

In the present specification, specific examples of the C₁-C₃ alkyl group are methyl, ethyl, propyl and isopropyl. The C₆-C₁₀ aromatic hydrocarbon group can be a substituted or unsubstituted aromatic hydrocarbon group. A part or all of hydrogen atoms of the aromatic hydrocarbon group may be substituted by a fluorine atom. Specific examples of the C₆-C₁₀ aromatic hydrocarbon group are phenyl, naphthyl, tolyl, xylyl, 3-trifluoromethylphenyl, 4-trifluoromethylphenyl and 3,5-di(trifluoromethylphenyl).

According to the present invention, there is obtained the curable silicone resin composition capable of forming a cured product with good heat resistant transparency. There are also obtained the cured product of the composition and the optical semiconductor device using the composition or cured product.

### BRIEF DESCRIPTION OF THE DRAWINGS

FIG. 1 is a schematic cross-sectional view showing an example of an optical semiconductor device according to the present invention.

FIG. 2 is a diagram showing a relationship between shear viscosity and temperature of compositions prepared in Examples and Comparative Examples (as compositions 1-1 to 1-5 and comparative composition 1-1).

FIG. 3 is a diagram showing a relationship between shear viscosity and temperature of compositions prepared in Examples and Comparative Examples (as compositions 4-1 to 4-3 and comparative composition 4-1).

FIG. 4 is a diagram showing a relationship between shear viscosity and time of compositions prepared in Examples (as compositions 1-1 and 1-6 to 1-9).

### DETAILED DESCRIPTION OF THE EMBODIMENTS

Hereinafter, the present invention will be described below in detail. It should however be noted that the present invention is not limited to the following description.

[Curable Silicone Resin Composition]

A curable silicone resin composition according to the present invention (occasionally simply referred to as the “composition of the present invention”) contains at least components (A), (B) and (C) in predetermined amounts. A cured product obtained by heating the composition of the present invention is suitably usable as an encapsulant of an optical semiconductor device. The respective components of the composition of the present invention will be explained below.

<Component (A)>

The component (A) is a silicone resin having a hydrogen atom bonded to silicon atom (as SiH group) as represented by the following formula [1]. The component (A) can be of one kind or can be a combination of two or more kinds.

(H-SiR¹₂O_{1/2})ₐ(SiR²₂O_{2/2})_{b}(R³SiO_{3/2})ₑ(SiO_{4/2})_{d} [1]

The above formula [1] is an average compositional formula. In the formula [1], R¹ is each independently a C₁-C₃ alkyl group; two R¹ may be of the same kind or different kinds; R² is each independently a C₁-C₃ alkyl group; two R² may be of the same kind or different kinds; R³ is a C₁-C₃ alkyl group or C₆-C₁₀ aromatic hydrocarbon group; a, b and c are each independently a number greater than 0 and smaller than 1; d is a number greater than or equal to 0 and smaller than 1; a, b, c and d satisfy the condition of a+b+c+d=1; and each of oxygen atoms in the respective structural units (SiR²₂O_{2/2}), (R³SiO_{3/2}) and (SiO_{4/2}) is a siloxane bond-forming oxygen atom or a silanol group-forming oxygen atom.

The C₁-C₃ alkyl group as R¹ is preferably methyl or ethyl. Particularly preferred is methyl.

The C₁-C₃ alkyl group as R² is preferably methyl or ethyl. Particularly preferred is methyl.

The C₁-C₃ alkyl group as R³ is preferably methyl or ethyl. Particularly preferred is methyl.

The C₆-C₁₀ aromatic hydrocarbon group as R³ is preferably phenyl, 3-trifluoromethylphenyl, 4-trifluoromethylphenyl or 3,5-di(trifluoromethylphenyl). Particularly preferred is phenyl.

There is no particular limitation on the combination of R¹, R² and R³. It is preferable to use methyl or ethyl as R¹, methyl or ethyl as R², and any of methyl, ethyl, phenyl, 3-trifluoromethylphenyl, 4-trifluoromethylphenyl and 3,5-di(trifluoromethylphenyl) as R³. It is particularly preferable to use methyl as R¹, methyl as R², and phenyl as R³.

There is no particular limitation on the number a as long as the number a is in the range of greater than 0 and smaller than 1 and satisfies the condition of a+b+c+d=1. The number a is preferably 0.05 to 0.40, more preferably 0.20 to 0.40. When the number a is greater than or equal to 0.05, the composition of the present invention shows good formability. When the number a is smaller than or equal to 0.40, the cured product of the present invention shows good mechanical strength.

There is no particular limitation on the number b as long as the number b is in the range of greater than 0 and smaller than 1 and satisfies the condition of a+b+c+d=1. The number b is preferably 0.10 to 0.80, more preferably 0.10 to 0.40. When the number b is greater than or equal to 0.10, the composition of the present invention shows good formability. When the number b is smaller than or equal to 0.80, the cured product of the present invention shows good mechanical strength.

There is no particular limitation on the number c as long as the number c is in the range of greater than 0 and smaller than 1 and satisfies the condition of a+b+c+d=1. The number c is preferably 0.10 to 0.80, more preferably 0.30 to 0.60. When the number c is greater than or equal to 0.10, the cured product of the present invention shows good mechanical strength. When the number c is smaller than or equal to 0.80, the composition of the present invention shows good formability.

There is no particular limitation on the number d as long as the number d is in the range of greater than or equal to 0 and smaller than 1 and satisfies the condition of a+b+c+d=1. The number d is preferably 0 to 0.70. In order for the cured product of the present invention to show good bonding strength and good hardness, it is particularly preferable that the number d is 0.10 to 0.30. In the case where the number d is 0, there exists no structural unit (SiO_{4/2}) in the formula [1].

The numbers a, b, c and dare preferably in the range of a:b:c:d=0.05 to 0.40:0.10 to 0.80:0.10 to 0.80:0 to 0.70, more preferably a:b:c:d=0.20 to 0.40:0.10 to 0.40:0.30 to 0.60:0.10 to 0.30.

In the case where the number d is 0, it is preferable that the numbers a, b and c are in range of a:b:c=0.05 to 0.40:0.10 to 0.80:0.10 to 0.80.

The numbers a, b, c and d can be determined by measuring ²⁹Si-NMR and ¹H-NMR spectra of the component (A) with a nuclear magnetic resonance spectrometer and complementarily analyzing the measurement results.

In the formula [1], the structural unit (SiR²₂O_{2/2}) may have a structure of the following formula [1-2]. It means that one of oxygen atoms bonded to silicon atom of the structural unit (SiR²₂O_{2/2}) may form a silanol group.

(R²SiXO_{1/2}) [1-2]

In the formula [1-2], R² has the same meaning as in the formula [1]; X is a hydroxy group.

The structural unit (SiR²₂O_{2/2}) may have a structural moiety surrounded by a broken line of the following formula [1-b] and also have a structural moiety surrounded by a broken line of the following formula [1-2-b]. It means that the structural unit (SiR²₂O_{2/2}) may not only have R² but also have a hydroxy group at a terminal end thereof to form a silanol group. In the following formulas [1-b] and [1-2-b], an oxygen atom of each Si—O—Si bond forms a siloxane bond with its adjacent silicon atom. One oxygen atom of the Si—O—Si bond is shared by the adjacent structural units and thus is expressed as “O_{1/2}”.

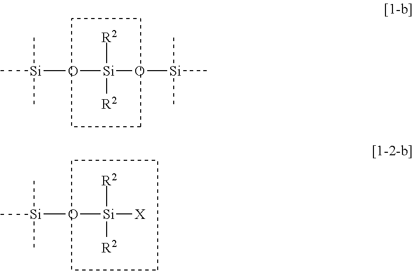

In the formulas [1-b] and [1-2-b], R² has the same meaning as in the formula [1]. In the formula [1-2-b], X is a hydroxy group.

The structural unit (R³SiO_{3/2}) may have a structure of the following formula [1-3] or [1-4]. It means that two oxygen atoms bonded to silicon atom of the structural unit (R³SiO_{3/2}) may each form a silanol group or one of oxygen atoms bonded to silicon atom of the structural unit (R³SiO_{3/2}) may form a silanol group.

(R³SiX₂O_{1/2}) [1-3]

(R³SiXO_{2/2}) [1-4]

In the formulas [1-3] and [1-4], R³ has the same meaning as in the formula [1]; X is a hydroxy group.

The structural unit (R³SiO_{3/2}) may have a structural moiety surrounded by a broken line of the following formula [1-c] and also have a structural moiety surrounded by a broken line of the following formula [1-3-c] or [1-4-c]. It means that the structural unit (R³SiO_{3/2}) may not only have R³ but also have a hydroxy group at a terminal end thereof to form a silanol group.

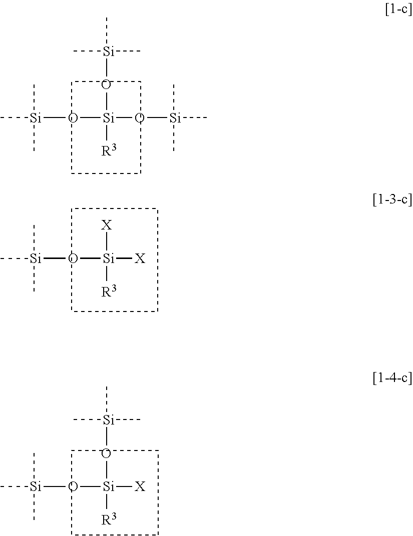

In the formulas [1-c], [1-3-c] and [1-4-c], R³ has the same meaning as in the formula [1]. In the formulas [1-3-c] and [1-4-c], X is a hydroxy group.

The structural unit (SiO_{4/2}) may have a structure of the following formula [1-5], [1-6] or [1-7]. It means that two or three oxygen atoms bonded to silicon atom of the structural unit (SiO_{4/2}) may each form a silanol group or one of oxygen atoms bonded to silicon atom of the structural unit (SiO_{4/2}) may form a silanol group.

(SiX₃O_{1/2}) [1-5]

(SiX₂O_{2/2}) [1-6]

(SiXO_{3/2}) [1-7]

In the formula [1-5], [1-6] and [1-7], X is a hydroxy group.

The structural unit (SiO_{4/2}) may have a structural moiety surrounded by a broken line of the following formula [1-d] and also have a structural moiety surrounded by a broken line of the following formula [1-5-d], [1-6-d] or [1-7-d]. It means that a hydroxy group may remain at a terminal end of the structural unit (SiO_{4/2}) to form a silanol group.

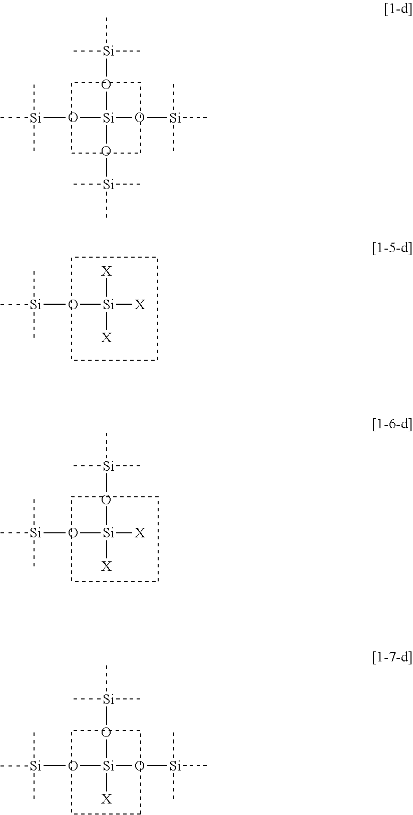

In the formulas [1-5], [1-6] and [1-7], X is a hydroxy group.

The component (A) has at least a hydrogen atom bonded to silicon atom (as SiH group) as mentioned above. There is no particular limitation on the number of hydrogen bonded to silicon atom in the component (A). Preferably, the component (A) has two or more hydrogen atoms bonded to silicon atoms in one molecule. It is particularly preferable that the amount of hydrogen bonded to silicon atom (as SiH group) in the component (A) is 1.0 to 4.0 mmol/g in order to obtain good cured product.

There is no particular limitation on the mass-average molecular weight of the component (A). The mass-average molecular weight of the component (A) is preferably 500 to 10,000, more preferably 800 to 7,000. When the mass-average molecular weight of the component (A) is 500 or larger, the cured product of the present invention shows good resin strength. When the mass-average molecular weight of the component (A) is 10,000 or smaller, the composition of the present invention shows good formability. It is particularly preferable that the mass-average molecular weight of the component (A) is 3,500 to 7,000 so that the cured product can ensure good mechanical strength in the case of d=1. Herein, the mass-average molecular weight refers to a value determined by gel permeation chromatography (GPC) on the basis of a calibration curve using polystyrene as a standard material. (The same applies to the following in the present embodiment.)

There is no particular limitation on the viscosity of the component (A). In view of the handling property, the viscosity of the component (A) at 25° C. is preferably 0.001 to 10,000,000 cP (centipoise), more preferably 0.01 to 500,000 cP. When the viscosity of the component (A) is higher than 10,000,000 cP, the composition may be poor in formability. In such a case, it is feasible to lower the viscosity by heating. The viscosity of the component (A) can be measured with a rotating viscometer.

There is also no particular limitation on the amount of Si—OH group in the component (A). The amount of Si—OH group in the component (A) is preferably 0.5 to 4.5 mmol/g, more preferably 1.0 to 3.5 mmol/g. When the amount of Si—OH group in the component (A) exceeds 4.5 mmol/g, there may occur air bubbles in the cured product.

<Component (B)>

The component (B) is a silicone resin having a vinyl group bonded to silicon atom (as Si—CH═CH₂ group) as represented by the following formula [2]. The component (B) can be of one kind or can be a combination of two or more kinds.

(CH₂═CH—SiR⁴₂O_{1/2})ₑ(SiR⁵₂O_{2/2})_{f}(R⁶SiO_{3/2})_{g}(SiO_{4/2})ₕ [2]

The above formula [2] is an average compositional formula. In the formula [2], R⁴ is each independently a C₁-C₃ alkyl group; two R⁴ may be of the same kind or different kinds; R⁵ is each independently a C₁-C₃ alkyl group; two R⁵ may be of the same kind or different kinds; R⁶ is a C₁-C₃ alkyl group or C₆-C₁₀ aromatic hydrocarbon group; e, f and g are each independently a number greater than 0 and smaller than 1; h is a number greater than or equal to 0 and smaller than 1; e, f g and h satisfy the condition of e+f+g+h=1; and each of oxygen atoms in the respective structural units (SiR⁵₂O_{2/2}), (R⁶SiO_{3/2}) and (SiO_{4/2}) is a siloxane bond-forming oxygen atom or a silanol group-forming oxygen atom.

The C₁-C₃ alkyl group as R⁴ is preferably methyl or ethyl. Particularly preferred is methyl.

The C₁-C₃ alkyl group as R⁵ is preferably methyl or ethyl. Particularly preferred is methyl.

The C₁-C₃ alkyl group as R⁶ is preferably methyl or ethyl. Particularly preferred is methyl.

The C₆-C₁₀ aromatic hydrocarbon group as R⁶ is preferably phenyl, 3-trifluoromethylphenyl, 4-trifluoromethylphenyl or 3,5-di(trifluoromethylphenyl). Particularly preferred is phenyl.

There is no particular limitation on the combination of R⁴, R⁵ and R⁶. It is preferable to use methyl or ethyl as R⁴, methyl or ethyl as R⁵, and any of methyl, ethyl, phenyl, 3-trifluoromethylphenyl, 4-trifluoromethylphenyl and 3,5-di(trifluoromethylphenyl) as R⁶. It is particularly preferable to use methyl as R⁴, methyl as R⁵, and methyl or phenyl as R⁶.

There is no particular limitation on the number e as long as the number e is in the range of greater than 0 and smaller than 1 and satisfies the condition of e+f+g+h=1. The number e is preferably 0.05 to 0.40, more preferably 0.15 to 0.30. When the number e is greater than or equal to 0.05, the composition of the present invention shows good formability. When the number e is smaller than or equal to 0.40, the cured product of the present invention shows good mechanical strength.

There is no particular limitation on the number f as long as the number f is in the range of greater than 0 and smaller than 1 and satisfies the condition of e+f+g+h=1. The number f is preferably 0.10 to 0.80, more preferably 0.20 to 0.70. When the number f is greater than or equal to 0.10, the composition of the present invention shows good formability. When the number f is smaller than or equal to 0.80, the cured product of the present invention shows good mechanical strength.

There is no particular limitation on the number g as long as the number g is in the range of greater than 0 and smaller than 1 and satisfies the condition of e+f+g+h=1. The number g is preferably 0.10 to 0.80, more preferably 0.20 to 0.70. When the number g is greater than or equal to 0.10, the cured product of the present invention shows good mechanical strength. When the number g is smaller than or equal to 0.80, the composition of the present invention shows good formability.

There is no particular limitation on the number h as long as the number h is in the range of greater than or equal to 0 and smaller than 1 and satisfies the condition of e+f+g+h=1. The number h is preferably 0 to 0.70. In order for the cured product of the present invention to show good bonding strength and good hardness, it is particularly preferable that the number h is 0.10 to 0.30. In the case where the number h is 0, there exists no structural unit (SiO_{4/2}) in the formula [2].

The numbers e, f g and h are preferably in the range of e:f:g:h=0.05 to 0.40:0.10 to 0.80:0.10 to 0.80:0 to 0.70, more preferably e:f:g:h=0.20 to 0.40:0.10 to 0.40:0.30 to 0.60:0.10 to 0.30.

In the case where the number h is 0, it is preferable that the numbers e, f and g are in the range of e:f:g=0.05 to 0.40:0.10 to 0.80:0.10 to 0.80.

The numbers e, f, g and h can be determined by measuring ²⁹Si-NMR and ¹H-NMR spectra of the component (B) with a nuclear magnetic resonance spectrometer and complementarily analyzing the measurement results.

In the formula [2], the structural unit (SiR⁵₂O_{2/2}) may have a structure of the following formula [2-2]. It means that one of oxygen atoms bonded to silicon atom of the structural unit (SiR⁵₂O_{2/2}) may form a silanol group.

(R²SiXO_{1/2}) [2-2]

In the formula [2-2], R⁵ has the same meaning as in the formula [2]; X is a hydroxy group.

The structural unit (SiR⁵₂O_{2/2}) may have a structural moiety surrounded by a broken line of the following formula [2-b] and also have a structural moiety surrounded by a broken line of the following formula [2-2-b]. It means that the structural unit (SiR⁵₂O_{2/2}) may not only have R⁵ but also have a hydroxy group at a terminal end thereof to form a silanol group. In the following formulas [2-b] and [2-2-b], an oxygen atom of each Si—O—Si bond forms a siloxane bond with its adjacent silicon atom. One oxygen atom of the Si—O—Si bond is shared by the adjacent structural units and thus is expressed as “O_{1/2}”.

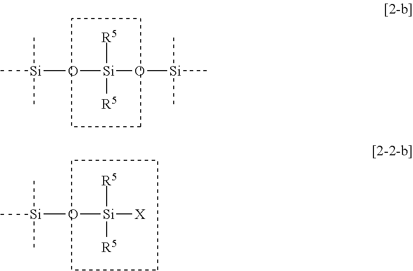

In the formulas [2-b] and [2-2-b], R⁵ has the same meaning as in the formula [2]. In the formula [2-2-b], X is a hydroxy group.

In the formula [2], the structural unit (R⁶SiO_{3/2}) may have a structure of the following formula [2-3] or [2-4]. It means that two oxygen atoms bonded to silicon atom of the structural unit (R⁶SiO_{3/2}) may each form a silanol group or one of oxygen atoms bonded to silicon atom of the structural unit (R⁶SiO_{3/2}) may form a silanol group.

(R⁶SiX₂O_{1/2}) [2-3]

(R⁶SiXO_{2/2}) [2-4]

In the formulas [2-3] and [2-4], R⁶ has the same meaning as in the formula [2]; and X is a hydroxy group.

The structural unit (R⁶SiO_{3/2}) may have a structural moiety surrounded by a broken line of the following formula [2-c] and also have a structural moiety surrounded by a broken line of the following formula [2-3-c] or [2-4-c]. It means that the structural unit (R⁶SiO_{3/2}) may not only have R⁶ but also have a hydroxy group at a terminal end thereof to form a silanol group.

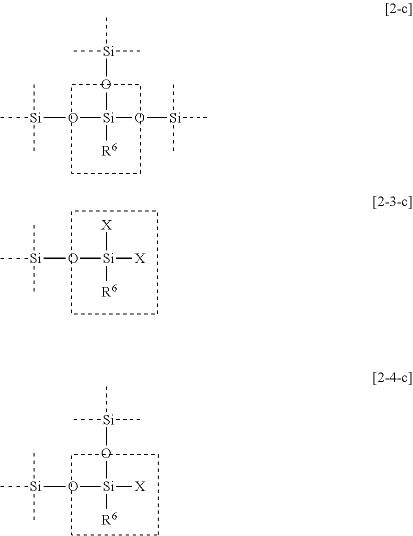

In the formulas [2-c], [2-3-c] and [2-4-c], R⁶ has the same meaning as in the formula [2]. In the formulas [2-3-c] and [2-4-c], X is a hydroxy group.

The structural unit (SiO_{4/2}) may have a structure of the following formula [2-5], [2-6] or [2-7]. It means that two or three oxygen atoms bonded to silicon atom of the structural unit (SiO_{4/2}) may each form a silanol group or one of oxygen atoms bonded to silicon atom of the structural unit (SiO_{4/2}) may form a silanol group.

(SiX₃O_{1/2}) [2-5]

(SiX₂O_{2/2}) [2-6]

(SiXO_{3/2}) [2-7]

In the formulas [2-5], [2-6] and [2-7], X is a hydroxy group.

The structural unit (SiO_{4/2}) may have a structural moiety surrounded by a broken line of the following formula [2-d] and also have a structural moiety surrounded by a broken line of the following formula [2-5-d], [2-6-d] or [2-7-d]. It means that a hydroxy group may remain at a terminal end of the structural unit (SiO_{4/2}) to form a silanol group.

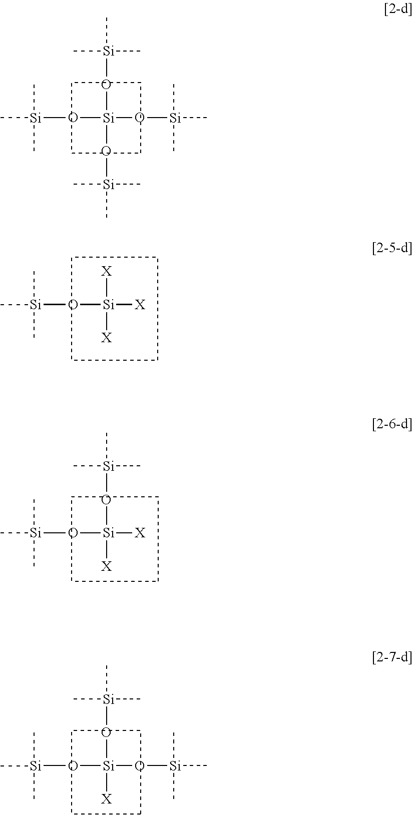

In the formulas [2-5-d], [2-6-d] and [2-7-d], X is a hydroxy group.

The component (B) has at least a vinyl group bonded to silicon atom (as Si—CH═CH₂ group) as mentioned above. There is no particular limitation on the number of vinyl group bonded to silicon atom in the component (B). Preferably, the component (C) has two or more vinyl groups bonded to silicon atoms in one molecule. It is particularly preferable that the amount of vinyl group bonded to silicon atom (as Si—CH═CH₂ group) in the component (C) is 0.5 to 4.0 mmol/g in order to obtain good cured product.

There is no particular limitation on the mass-average molecular weight of the component (B). The mass-average molecular weight of the component (B) is preferably 500 to 10,000, more preferably 800 to 7,000. When the mass-average molecular weight of the component (B) is 500 or larger, the cured product of the present invention shows good resin strength. When the mass-average molecular weight of the component (B) is 10,000 or smaller, the composition of the present invention shows good formability. It is particularly preferable that the mass-average molecular weight of the component (B) is 3,500 to 7,000 so that the cured product of the present invention can ensure good mechanical strength in the case of h=1.

There is no particular limitation on the viscosity of the component (B). In view of the handling property, the viscosity of the component (B) at 25° C. is preferably 0.001 to 10,000,000 cP, more preferably 0.001 to 500,000 cP. When the viscosity of the component (B) is higher than 10,000,000 cP, the composition may be poor in formability. In such a case, it is feasible to lower the viscosity by heating. The viscosity of the component (B) can be measured with a rotating viscometer.

There is also no particular limitation on the amount of Si—OH group in the component (B). The amount of Si—OH group in the component (B) is preferably 0.5 to 6.0 mmol/g, more preferably 1.0 to 3.5 mmol/g. When the amount of Si—OH group in the component (B) exceeds 6.0 mmol/g, there may occur air bubbles in the cured product.

<Component (C)>

The component (C) is added to accelerate the after-mentioned addition curing reaction between the SiH group of the component (A) and the Si—CH═CH₂ group of the component (B). The component (C) can be of one kind or can be a combination of two or more kinds.

There is no particular limitation on the kind of the component (C). Specific examples of the component (C) include chloroplatinate, alcohol-modified chloroplatinate, platinum-carbonylvinylmethyl complex, platinum-divinyltetramethyldisiloxane complex (Karstedt catalyst), platinum-cyclovinylmethylsiloxane complex and platinum-octylaldehyde complex. Among others, preferred are platinum-divinyltetramethyldisiloxane complex (Karstedt catalyst) and platinum-cyclovinylmethylsiloxane complex.

<Other Additives>

The composition of the present invention may contain, in addition to the above components (A) to (C), a curing retardant for the purpose of improving the storage stability and handling property of the composition and adjusting the hydrosilylation reactivity of the composition during the curing process. The composition of the present invention can be cured at a relatively low temperature and thus can suitably be used for coating/encapsulation of heat-sensitive optical semiconductor elements. Depending on the coating/encapsulation work environment, the curing retardant may preferably be added to adjust the curing rate of the composition in view of the storage stability and handling property of the composition. There is no particular limitation on the kind of the curing retardant as long as the curing retardant is a compound having a curing retarding effect on the component (C). Any conventionally known curing retardant may be used. For example, there can be used any of aliphatic unsaturated bond-containing compounds, an organic phosphorus compounds, nitrogen-containing compounds, organic sulfur compounds and organic peroxide compounds as the curing retardant. These compounds may be used solely or in combination of two or more thereof.

Specific examples of the aliphatic unsaturated bond-containing compounds include: propargyl alcohols such as 2-methyl-3-butyn-2-ol, 2-phenyl-3-butyn-2-ol, 3,5-dimethyl-1-hexyn-3-ol and 1-ethynyl-1-cyclohexanol; ene-yne compounds; and maleates such as maleic anhydride and dimethyl maleate.

Specific examples of the organic phosphorus compounds include triorganophosphines, diorganophosphines, organophosphines and triorganophosphites.

Specific examples of the nitrogen-containing compounds include: N,N,N′,N′-tetrasubstituted alkylenediamines such as N,N,N′,N′-tetramethylethylenediamine and N,N,N′,N′-tetraethylethylenediamine; N,N-disubstituted alkylenediamines such as N,N-dimethylethylenediamine, N,N-diethylethylenediamine, N,N-dibutylethylenediamine, N,N-dibutyl-1,3-propanediamine, N,N-dimethyl-1,3-propanediamine and N,N-dibutyl-1,4-butanediamine; trisubstituted amines such as tributylamine; benzotriazole; and 2,2′-bipyridine.

Specific examples of the organic sulfur compounds include organomercaptans, diorganosulfides, hydrogen sulfide, benzothiazole, thiazole and benzothiazole disulfide.

Specific examples of the organic peroxide compounds are di-tert-butyl peroxide, dicumyl peroxide, benzoyl peroxide and tert-butyl peroxybenzoate.

Among the above curing retardants, it is preferable to use any of aliphatic unsaturated bond-containing compounds and nitrogen-containing compounds. More specifically, maleates, propargyl alcohols and N,N,N′,N′-tetrasubstituted alkylenediamines are preferred. Particularly preferred are dimethyl maleate, 2-methyl-3-butyn-2-ol, 1-ethynyl-1-cyclohexanol and N,N,N′,N′-tetramethylethylenediamine.

There is no particular limitation on the amount of the curing retardant in the composition of the present invention. It suffices to add the curing retardant in an amount of 20 to 200 equivalents relative to 1 equivalent of platinum atom of the component (C). The amount of the curing retardant is however not limited to such an amount. The degree of the curing retarding effect of the curing retardant varies depending on the chemical structure of the curing retardant. It is thus preferable to optimize the amount of the curing retardant in accordance with the kind of the curing retardant used. With the addition of the optimum amount of the curing retardant, the composition of the present invention shows good long-term storage stability at room temperature and thermal curability. (Herein, the “room temperature” refers to an ambient temperature with no heating or no cooling and generally ranges from 15 to 30° C. The same applies to the following.)

The composition of the present invention may contain a bonding aid, in addition to the above components (A) to (C), for the purpose of improving the bonding property of the composition. A silane coupling agent, a hydrolysis condensate thereof or the like can be used as the bonding aid. Specific examples of the silane coupling agent include those of known kinds, such as: epoxy group-containing silane coupling agents e.g. γ-(glycidoxypropyl)trimethoxysilane; (meth)acrylic group-containing silane coupling agents; isocyanate group-containing silane coupling agents; isocyanurate group-containing silane coupling agents; amino group-containing silane coupling agents; and mercapto group-containing silane coupling agents.

There is no particular limitation on the amount of the bonding aid in the composition of the present invention. The amount of the bonding aid in the composition of the present invention is preferably 1 to 20 mass %, more preferably 5 to 15 mass %.

The composition of the present invention may contain an conventionally known antioxidant for the purpose of suppressing coloring, oxidation degradation etc. of the cured product. As the antioxidant, there can be used any of phenolic antioxidants, thioether antioxidants and phosphorus-containing antioxidants. Among others, phenolic antioxidants and thioether antioxidants are preferred. Particularly preferred are thioether antioxidants. These antioxidants may be used solely or in combination of two or more kinds thereof.

Specific examples of the phenolic antioxidants include 1,3,5-tris(3,5-di-tert-butyl-4-hydroxybenzyl)-1,3,5-triazin-2,4,6-(1H,3H,5H)-trion, 4,4′,4′-(1-methylpropanyl-3-ylidene)tris(6-tert-butyl-m-cresol), 6 6′-di-tert-butyl-4 4′-butylidene-di-m-cresol, octadecyl-3-(3,5-di-tert-butyl-4-hydroxyphenyl)propionate, pentaerythritol tetrakis[3-(3,5-di-tert-butyl-4-hydroxyphenyl)propionate], 3,9-bis {2-[3-(3-tert-butyl-4-hydroxy-5-methylphenyl)propionyloxy]-1,1-dimethylethyl}-2, 4,8,10-tetraoxaspiro[5.5]undecene and 1,3,5-tris(3,5-di-tert-butyl-4-hydroxyphenylmethyl)-2,4,6-trimethylbenzene.

Specific examples of the thioether antioxidants include 2,2-bis({[3-(dodecylthio)propionyl]oxy}methyl)-1,3-propanediyl=bis[3-(dodecylthio)propionate] and di(tridecyl)3,3′-thiodipropionate.

Specific examples of the phosphorus-containing antioxidants include 3,9-bis(octadecyloxy)-2,4,8,10-tetraoxa-3,9-diphosphaspiro[5.5]undecene, 3,9-bis(2,6-di-tert-butyl-4-methylphenoxy)-2,4,8,10-tetraoxa-3,9-diphosphaspiro[5.5]undecene, 2,2′-methylenebis(4,6-di-tert-butylphenyl)-2-ethylhexyl phosphite, tris(2,4-di-tert-butylphenyl)phosphite, tris(nonylphenyl)phosphite, tetra-C₁₂₋₁₅-alkyl(propane-2,2-diylbis(4,1-phenylene))bis(phosphite), 2-ethylhexyldiphenyl phosphite, isodecyldiphenyl phosphite, triisodecyl phosphite and triphenyl phosphite.

The antioxidant can be provided as a commercially available product or can be synthetized as appropriate. Examples of the commercially available antioxidant are those available (from Adeka Corporation) under the trade names of ADK STAB AO-20, AO-30, AO-40, AO-50, AO-50F, AO-60, AO-60G, AO-80, AO-330, AO-412S, AO-503, PEP-8, PEP-8W, PEP-36, PEP-36A, HP-10, 2112, 2112RG, 1178, 1500, C, 135A, 3010 and TPP.

There is no particular limitation on the amount of the antioxidant in the composition of the present invention as long as the antioxidant is added in its effective amount within the range that does not impair the transparency and other features of the cured product. It suffices to add the antioxidant in an amount of 0.001 to 2 mass % relative to the total mass of the composition of the present invention. The amount of the antioxidant in the composition of the present invention is preferably 0.01 to 1 mass % relative to the total mass of the composition of the present invention. When the amount of the antioxidant is in the above range, the antioxidant sufficiently exerts its oxidation preventing effect so as to obtain the cured product with good engineering characteristics while suppress coloring, whitening, oxidation degradation etc. of the cured product.

The composition of the present invention may contain an conventionally known light stabilizer for the purpose of imparting resistance to photo degradation by light energy such as sunlight or fluorescent light. As the light stabilizer, there can suitably be used a hindered amine stabilizer capable of trapping radicals generated by photo oxidation (photo degradation). It is feasible to increase the oxidation prevention effect by the combined use of the light stabilizer with the above-mentioned antioxidant. Specific examples of the light stabilizer include bis(2,2,6,6-tetramethyl-4-piperidyl)sebacate, 4-benzoyl-2,2,6,6-tetramethylpiperidine, tetrakis(1,2,2,6,6-pentamethyl-4-piperidyl)butane-1,2,3,4-tetracarboxylate and bis(1-undecanoxy-2,2,6,6-tetramethylpiperidin-4-yl)carbonate. Among others, bis(2,2,6,6-tetramethyl-4-piperidyl)sebacate is particularly preferred.

The light stabilizer can be provided as a commercially available product or can be synthetized as appropriate. Examples of the commercially available antioxidant are those available (from Adeka Corporation) under the trade names of ADK STAB LA-77Y, LA-77G and LA-82.

There is no particular limitation on the amount of the light stabilizer in the composition of the present invention as long as the light stabilizer is added in its effective amount within the range that does not impair the transparency and other features of the cured product. It suffices to add the light stabilizer in an amount of 0.01 to 5 mass % relative to the total mass of the curable silicone resin composition of the present invention. The amount of the light stabilizer in the composition of the present invention is preferably 0.05 to 0.5 mass % relative to the total mass of the composition of the present invention.

The composition of the present invention may contain a phosphor as an arbitrary component. There is no particular limitation on the kind of the phosphor. The phosphor can be any of yellow, red, green and blue phosphors widely used for light-emitting diodes (LED), such as oxide phosphors, oxynitride phosphors, nitride phosphors, sulfide phosphors and oxysulfide phosphors.

Specific examples of the oxide phosphors include cerium-ion-doped green- to yellow-emitting yttrium-aluminum-garnet (YAG) phosphors, cerium-ion-doped yellow-emitting terbium-aluminum-garnet (TAG) phosphors and cerium- or europium-ion-doped green- to yellow-emitting silicate phosphors. Specific examples of the oxynitride phosphors include europium-ion-doped red- to green-emitting silicon-aluminum-oxide-nitrogen (SIALON) phosphors. Specific examples of the nitride phosphors include europium-ion-doped red-emitting calcium-strontium-aluminum-silicon-nitrogen (CASN) phosphors. Specific examples of the sulfide phosphors include copper- or aluminum-ion-doped green-emitting ZnS phosphors. Specific examples of the oxysulfide phosphors include europium-ion-doped red-emitting Y₂O₂S phosphors. These phosphors may be used solely or in combination of two or more thereof.

There is no particular limitation on the amount of the phosphor in the composition of the present invention. The amount of the phosphor in the composition of the present invention is preferably 10 to 70 mass %, more preferably 20 to 50 mass %.

The composition of the present invention may contain an inorganic particulate material for the purpose of improving the optical characteristics, workability, mechanical characteristics and physical/chemical properties of the cured product.

The kind of the inorganic particulate material can be selected as appropriate depending on the purpose of use. The inorganic particulate material can be of one kind or can be a combination of two or more kinds. Further, the inorganic particulate material may be surface-treated with a surface treatment agent, such as silane coupling agent, for improvement in dispersibility.

Specific examples of the inorganic particulate material include: particles of silica and inorganic oxides such as barium titanate, titanium oxide, zirconium oxide, niobium oxide, aluminum oxide, cerium oxide and yttrium oxide: particles of nitrides such as silicon nitride, boron nitride and aluminum nitride; particles of carbides such as silicon carbide; particles of carbon compounds; and particles of diamond. The inorganic particulate material is not limited to these kinds. Any other inorganic particulate material may be selected and used depending on the purpose of use.

The inorganic particulate material can be provided in any form such as powder form, slurry form etc. depending on the purpose of use. In accordance with the transparency required, it is preferable to set the refractive index of the inorganic particulate material equal to that of the cured product of the present invention or to add the inorganic particulate material in the form of a transparent aqueous or solvent sol to the composition of the present invention.

There is no particular limitation on the average particle size of the inorganic particulate material. The average particle size of the inorganic particulate material can be selected as appropriate depending on the purpose of use. In general, the average particle size of the inorganic particulate material is approximately equal to or smaller than 1/10 of that of the above-mentioned phosphor. Herein, the “average particle size” of the inorganic particulate material refers to an arithmetic average value of longer diameters of 20 particles arbitrarily selected from 50 or more particles observed by a scanning electron microscope (abbreviation: SEM).

There is no particular limitation on the amount of the inorganic particulate material in the composition of the present invention as long as the inorganic particulate material is added within the range that does not impair the transparency and other features of the cured product. When the inorganic particulate material is added in too small amount, the desired effect of the inorganic particulate material may not be obtained. When the inorganic particulate material is added in too large amount, the features such as heat resistant transparency, adhesion, transparency, formability and hardness of the cured product may be impaired. It suffices to add the inorganic particulate material in an amount of 1 to 50 mass % relative to the total mass of the composition of the present invention. The amount of the inorganic particulate material in the composition of the present invention is preferably 5 to 35 mass % relative to the total mass of the composition of the present invention.

The composition of the present invention may further contain a mold releasing agent, a resin modifying agent, a coloring agent, a diluent, an antimicrobial agent, a fungicide, a leveling agent, an anti-sagging agent and the like within the range that does not impair the transparency and other features of the cured product.

<Mixing Ratio of Components (A), (B) and (C)>

There is no particular limitation on the mixing ratio of the components (A) and (B) in the composition of the present invention. The components (A) and (B) are mixed as appropriate with reference to the mole number ratio of the SiH group in the molecule of the component (A) and the Si—CH═CH₂ group in the molecule of the component (B). The ratio of the mole number of the SiH group in the molecule of the component (A) to the mole number of the Si—CH═CH₂ group in the molecule of the component (B) is preferably in the range of 0.8:0.2 to 0.5:0.5. When the ratio of the mole number of the SiH group to the mole number of the Si—CH═CH₂ group is 0.8 or less, the composition of the present invention shows good formability. When the ratio of the mole number of the SiH group to the mole number of the Si—CH═CH₂ group is 0.5 or more, the cured product of the present invention shows good heat resistant transparency.

The amount of the component (C) in the composition of the present invention is preferably set such that the component (C) contains 0.003 to 3.0 ppm, more preferably 0.003 to 2.0 ppm, of platinum atom in mass units relative to the total mass of the components (A), (B) and (C). When the platinum amount of the component (C) is 0.003 ppm or more, the addition curing reaction of the components (A) and (B) proceeds favorably. When the platinum amount of the component (C) is 3.0 ppm, the cured product shows good heat resistant transparency so that coloring of the cured product can be suppressed even under long-term heating. It is preferable to add the component (C) in as small an amount as possible because the smaller the amount of the component (C) added, the more likely the cured product will show good heat resistant transparency.

In the composition of the present invention, it suffices that the total amount of silanol (Si—OH) group in the components (A) and (B) is in the range of 0.5 to 5.0 mmol/g. The total amount of silanol group in the components (A) and (B) is preferably 1.0 to 3.0 mmol/g, more preferably 1.5 to 3.0 mmol/g. When the total amount of silanol group in the components (A) and (B) of the composition exceeds 5.0 mmol/g, there may occur air bubbles in the cured product of the composition. The occurrence of such air bubbles becomes a cause of deterioration in the transparency and heat resistant transparency of the cured product. Further, the desired cured product may not be obtained due to insufficient curing of the composition when the total amount of silanol group in the components (A) and (B) of the composition exceeds 5.0 mmol/g.

In the case of using the component (A) having d=0 and having a mass-average molecular weight of 3,500 to 7,000 in combination with the component (B) having h=0 and having a mass-average molecular weight of 3,500 to 7,000, the total amount of silanol (Si—OH) group in the components (A) and (B) may be in the range of 1.5 to 5.0 mmol/g. In this case, the total amount of silanol group in the components (A) and (B) is preferably 1.7 to 3.0 mmol/g. In order for the cured product to show good adhesion to packages of various sizes, it is particularly preferable that the total amount of silanol group in the components (A) and (B) is 1.9 to 2.7 mmol/g.

The amount of silanol group in the components (A) and (B) can be determined by measuring ²⁹Si-NMR and ¹H-NMR spectra of the respective components with a nuclear magnetic resonance spectrometer and complementarily analyzing the measurement results.

There is no particular limitation on the viscosity of the composition of the present invention. In view of the handling property, the viscosity of the composition at 25° C. is preferably 0.001 to 10,000,000 cP, more preferably 0.001 to 500,000 cP. When the viscosity of the composition is higher than 10,000,000 cP, the composition may be poor in formability. In such a case, it is feasible to lower the viscosity by heating. The viscosity of the composition can be measured with a rotating viscometer.

<Preparation of Curable Silicone Resin Composition>

The composition of the present invention is prepared by mixing the components (A), (B) and (C) and optionally other additives. It is preferable that the components (A), (B) and (C) and optionally other additives are substantially uniformly dispersed by mixing. There is no particular limitation on the technique for mixing of the respective components. For example, the mixing is performed with the use of a universal mixer, a kneader or the like. The component (C) may be mixed with the component (A) and/or the component (B) in advance. In order to stably store the composition for a long term, the components (B) and (C) may be stored in separate containers. For example, it is feasible to store a first composition containing a part of the component (A) and the component (C) in one container while storing a second composition containing the remaining part of the component (A) and the component (B) in another container, obtain the composition by mixing these first and second compositions together immediately before the use, and then, use the composition after vacuum defoaming.

(Formation of Component (A))

There is no particular limitation on the method for formation of the component (A). For example, the component (A) is formed by reacting a product of hydrolysis and condensation of a dialkoxysilane compound of the following general formula [3], a trialkoxysilane compound of the following general formula [4] and a tetraalkoxysilane compound of the following general formula [5] (sometimes referred to as “hydrolysis condensate [I]”) with a silane compound of the following general formula [9-1], [9-2], [9-3] or [9-4].

R²₂Si(OR⁷)₂ [3]

R³Si(OR)₃ [4]

Si(OR⁹)₄ [5]

In the general formula [3], R² has the same meaning as in the formula [1]; R⁷ is each independently a C₁-C₃ alkyl group; and two R⁷ may be of the same kind or different kinds. In the general formula [4], R³ has the same meaning as in the formula [1]; R⁸ is each independently a C₁-C₃ alkyl group; and three R⁸ may be of the same kind or different kinds. In the general formula [5], R⁹ is each independently a C₁-C₃ alkyl group; and four R⁹ may be of the same kind or different kinds.

H—SiR¹₂Cl [9-1]

H—SiR¹₂(OH) [9-2]

H—SiR¹₂(OR¹³) [9-3]

(H—SiR¹₂)₂O [9-4]

In the general formulas [9-1], [9-2], [9-3] and [9-4], R¹ has the same meaning as in the formula [1]. In the general formula [9-3], R¹³ is a C₁-C₃ alkyl group.

Hereinafter, the dialkoxysilane compound of the general formula [3], the trialkoxysilane compound of the general formula [4] and the tetraalkoxysilane compound of the general formula [5] are sometimes referred to as “dialkoxysilane compound [3]”, “trialkoxysilane compound [4]” and “tetraalkoxysilane compound [5]”, respectively. Further, the silane compounds of the general formulas [9-1], [9-2], [9-3] and [9-4] are sometimes referred to as “chlorosilane compound [9-1]”, “silanol compound [9-2]”, “monoalkoxysilane compound [9-3]” and “disiloxane compound [9-4]”, respectively. The silane compounds of the general formulas [9-1], [9-2], [9-3] and [9-4] may be generically called “silane compound [9]” without being distinguished from each other.

Specific examples of the dialkoxysilane compound [3] include, but are not limited to, dimethyldimethoxysilane, dimethyldiethoxysilane, diethyldimethoxysilane and diethyldiethoxysilane. Among others, dimethyldimethoxysilane and dimethyldiethoxysilane are preferred.

Specific examples of the trialkoxysilane compound [4] include, but are not limited to, methyltrimethoxysilane, methyltriethoxysilane, ethyltrimethoxysilane, ethyltriethoxysilane, vinyltrimethoxysilane, vinyltriethoxysilane, phenyltrimethoxysilane, phenyltriethoxysilane, 3-(trifluoromethyl)phenyltrimethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane, 3,5-(ditrifluoromethyl)phenyltriethoxysilane, naphthyltrimethoxysilane and naphthyltriethoxysilane. Among others, methyltrimethoxysilane, methyltriethoxysilane, phenyltrimethoxysilane, phenyltriethoxysilane, 3-(trifluoromethyl)phenyltrimethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane and 3,5-(ditrifluoromethyl)phenyltriethoxysilane are preferred. Particularly preferred are methyltrimethoxysilane, methyltriethoxysilane, phenyltrimethoxysilane and phenyltriethoxysilane.

Specific examples of the tetraalkoxysilane compound [5] include, but are not limited to, tetramethoxysilane, tetraethoxysilane, tetra-n-propoxysilane and tetraisopropoxysilane. Among others, tetramethoxysilane and tetraethoxysilane are preferred.

There is no particular limitation on the combination of the dialkoxysilane compound [3], the trialkoxysilane compound [4] and the tetraalkoxysilane compound [5] used for the formation of the component (A). Each of the dialkoxysilane compound [3], the trialkoxysilane compound [4] and the tetraalkoxysilane compound [5] can be of one kind or can be a combination of two or more kinds. It is preferable to use, in combination, one or more selected from the group consisting of dimethyldimethoxysilane, dimethyldiethoxysilane, diethyldimethoxysilane and diethyldiethoxysilane as the dialkoxysilane compound [3], one or more selected from the group consisting of methyltrimethoxysilane, methyltriethoxysilane, ethyltrimethoxysilane, ethyltriethoxysilane, vinyltrimethoxysilane, vinyltriethoxysilane, phenyltrimethoxysilane, phenyltriethoxysilane, 3-(trifluoromethyl)phenyltrimethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane and 3,5-(ditrifluoromethyl)phenyltriethoxysilane as the trialkoxysilane compound [4], and one or more selected from the group consisting of tetramethoxysilane, tetraethoxysilane and tetraisopropoxysilane as the tetraalkoxysilane compound [5]. It is particularly preferable to use, in combination, one or more selected from the group consisting of dimethyldimethoxysilane and dimethyldiethoxysilane as the dialkoxysilane compound [3], one or more selected from the group consisting of methyltrimethoxysilane, methyltriethoxysilane, phenyltrimethoxysilane and phenyltriethoxysilane as the trialkoxysilane compound [4], and one or more selected from the group consisting of tetramethoxysilane and tetraethoxysilane as the tetraalkoxysilane compound [5].

Specific examples of the chlorosilane compound [9-1] include, but are not limited to, chlorodimethylsilane and chlorodiethylsilane. Among others, chlorodimethylsilane is preferred.

Specific examples of the silanol compound [9-2] include, but are not limited to, dimethylsilanol and diethylsilanol. Among others, dimethylsilanol is preferred.

Specific examples of the monoalkoxysilane compound [9-3] include, but are not limited to, dimethylmethoxysilane, dimethylethoxysilane, diethylmethoxysilane and diethylethoxysilane. Among others, dimethylmethoxysilane and dimethylethoxysilane are preferred.

Specific examples of the disiloxane compound [9-4] include, but are not limited to, 1,1,3,3-tetramethyldisiloxane and 1,1,3,3-tetraethyldisiloxane. Among others, 1,1,3,3-tetramethyldisiloxane is preferred.

The following is one example of the method for production of the hydrolysis condensate [I]. First, a reaction solution is provided by placing predetermined amounts of the dialkoxysilane compound [3], the trialkoxysilane compound [4] and optionally the tetraalkoxysilane compound [5] into a reactor at room temperature, and then, adding a required amount of water for hydrolysis of the respective alkoxysilane compounds, a reaction solvent as needed and optionally a catalyst for acceleration of the condensation reaction. The order of introduction of these reaction materials is not limited to the above. The reaction materials can be introduced into the reactor in any arbitrary order. Next, the reaction solution is reacted by stirring for a predetermined time at a predetermined temperature. As a result of the reaction, the hydrolysis condensate [I] is obtained. At this time, it is preferable to use the reactor with a reflux unit in order to prevent the unreacted raw alkoxysilane compounds, water, reaction solvent and/or catalyst from being evaporated from the reaction system.

There is no particular limitation on the amounts of the dialkoxysilane compound [3], the trialkoxysilane compound [4] and the tetraalkoxysilane compound [5] used for the production of the hydrolysis condensate [1]. In view of the physical properties of the component (A), the dialkoxysilane compound [3] and the trialkoxysilane compound [4] are preferably used in amounts of 85:15 to 15:85, more preferably 85:15 to 30:70, in terms of molar ratio. When the molar ratio of the dialkoxysilane compound [3] is lower than 15, the molecular weight of the hydrolysis condensate may become larger than a desired level. When the molar ratio of the dialkoxysilane compound [3] is higher than 85, the molecular weight of the hydrolysis condensate may become smaller than a desired level. In the case of using the tetraalkoxysilane compound [5], the amount of the tetraalkoxysilane compound [5] used is preferably 1 to 80 mol, more preferably 1 to 60 mol, per 100 mol of the sum of the dialkoxysilane, trialkoxysilane and tetraalkoxysilane compounds [3], [4] and [5].

There is no particular limitation on the amount of water used for the production of the hydrolysis condensate [I]. In view of the reaction efficiency, the amount of the water used is preferably 1.5 to 5 times relative to the total molar equivalents of alkoxy group in the raw alkoxysilane compounds, i.e., the total molar equivalents of alkoxysilane group in the dialkoxysilane, trialkoxysilane and tetraalkoxysilane compounds [3], [4] and

When water is used in an amount of 1.5 times or more relative to the total molar equivalents of alkoxy group in the alkoxysilane compounds, the hydrolysis of the alkoxysilane compounds proceeds favorably. There is no need to use water in an amount of more than 5 times relative to the total molar equivalents of alkoxy group in the alkoxysilane compounds.

In the production of the hydrolysis condensate [I], it is feasible to use the reaction solvent although the reaction can be performed in the presence of no solvent.

There is no particular limitation on the kind of the reaction solvent as long as the reaction solvent does not interfere with the reaction for the production of the hydrolysis condensate

In particular, a hydrophilic organic solvent such as alcohol is preferred as the reaction solvent. Specific examples of the alcohol solvent include methanol, ethanol, n-propanol, isopropanol and butanol. The amount of the reaction solvent used is preferably 0.1 to 1000 mass %, more preferably 1 to 300 mass %, relative to the total amount of the alkoxysilane compounds. The reaction solvent is not necessarily used because an alcohol generated by the reaction of the raw alkoxysilane compounds plays a role of the reaction solvent.

In the production of the hydrolysis condensate [I], an acid catalyst or a basic catalyst can be used as the catalyst. An acid catalyst is preferred for ease of control of the molecular weight of the hydrolysis condensate [I]. There is no particular limitation on the kind of the acid catalyst. Specific examples of the acid catalyst include acetic acid, hydrochloric acid, nitric acid, sulfuric acid, hydrofluoric acid, trifluoromethanesulfonic acid, tosic acid and trifluoroacetic acid. Among others, acetic acid, hydrochloric acid, nitric acid, sulfuric acid and hydrofluoric acid are preferred for ease of removal of the catalyst after the completion of the reaction. Particularly preferred is acetic acid. There is no particular limitation on the kind of the basic catalyst. Specific examples of the basic catalyst include sodium hydroxide, potassium hydroxide, lithium hydroxide, magnesium hydroxide, sodium carbonate, potassium carbonate, cesium carbonate, trimethylamine and pyridine.

The amount of the catalyst used for the production of the hydrolysis condensate [I] is preferably 0.001 to 5 mass %, more preferably 0.005 to 1 mass %, relative to the total amount of the alkoxysilane compounds, the solvent and water.

There is no particular limitation on the reaction time in the production of the hydrolysis condensate [I]. The reaction time is generally in the range of 3 to 15 hours.

There is also no particular limitation on the reaction temperature. The reaction temperature is generally in the range of 60 to 120° C., preferably 80 to 100° C.

After the reaction, it is preferable to separate the hydrolysis condensate [I] by purification from the reaction system for ease of handling of the hydrolysis condensate [I].

There is no particular limitation on the technique for separation of the hydrolysis condensate [I]. For example, the hydrolysis condensate [I] is separated by extraction and, more specifically, by, after the reaction, cooling the reaction solution to room temperature and bringing the reaction solution into contact with a nonaqueous organic solvent as an extraction solvent. After the extraction, the catalyst is removed from the extracted solution. There is no particular limitation on the technique for removal of the catalyst. In the case where the catalyst used (e.g. acetic acid) is soluble in water, for example, it is feasible to remove the catalyst by washing the extracted solution with water. The hydrolysis condensate [I] is obtained with high purity by, after the removal of the catalyst, removing water from the system with the addition of a drying agent, removing the drying agent and then removing the extraction solvent under reduced pressure. Alternatively, the extraction solvent and water may simultaneously be removed under reduced pressure from the solution, without using the drying agent, after the removal of the catalyst.

The nonaqueous organic solvent is usable as the extraction solvent. There is no particular limitation on the kind of the nonaqueous organic solvent. An aromatic hydrocarbon or an ether can be used as the nonaqueous organic solvent. Specific examples of the nonaqueous organic solvent include, but are not limited to, toluene, diethyl ether, isopropyl ether and dibutyl ether.

There is no particular limitation on the kind of the drying agent as the drying agent is capable of removing water from the system and separating water from the hydrolysis condensate [I]. A solid drying agent is preferred as the drying agent.

Specific examples of the drying agent include, but are not limited to, magnesium sulfate.

After the separation and purification, the hydrolysis condensate [I] may be subjected to further condensation in a solvent by heating under reflux or by heating and stirring in the presence of no solvent. It is feasible to increase the molecular weight of the hydrolysis condensate [1] by this condensation reaction. In the case of using the solvent, the hydrolysis condensate [I] and the solvent are put into a reactor with heating/reflux equipment. The resulting solution of the hydrolysis condensate [I] is heated under reflux so as to form an azeotropic mixture with water in the system with the progress of the condensation reaction. The solution may be mixed with e.g. tosic acid and then heated under reflux. There is no particular limitation on the kind of the solvent used as long as the hydrolysis condensate [I] is dissolved in the solvent and the resulting solution is subjected to heating under reflux. Specific examples of the solvent include: aromatic hydrocarbons such as toluene, xylene and benzene; ethers such as diethyl ether and diisopropyl ether; and esters such as ethyl acetate. In the case of using no solvent, the hydrolysis condensate [I] is put into a reactor with heating/stirring equipment. Then, the hydrolysis condensate [I] is stirred while heating at 100 to 150° C. At this time, it is preferable to use the reactor with a reflux unit (such as condenser) in order to suppress a change in the composition ratio of the hydrolysis condensate [I]. After the heating and stirring, the resulting liquid is cooled to room temperature. The above series of reaction operation can be performed repeatedly. There is no particular limitation on the number of repetition of the reaction operation. It is preferable to perform the reaction operation one to four times.

Next, the method for formation of the component (A) by reaction of the hydrolysis condensate [I] and the silane compound [9] will be explained below. There is no particular limitation on the method for formation of the component (A). For example, the following two, first and second methods are applicable. The first method is a method for forming the component (A) by reacting the hydrolysis condensate [I] with the chlorosilane compound [9-1] as one kind of silane compound [9] in a nonaqueous organic solvent. The second method is a method for forming the component (A) by reacting the hydrolysis condensate [I] with the silanol compound [9-2], the monoalkoxysilane compound [9-3] or the disiloxane compound [9-4] as one kind of silane compound [9] in the presence of an acid in a mixed solvent of a nonaqueous organic solvent and an alcoholic solvent. These two methods will be explained in more detail below.

(First Method)

In the first method, a predetermined amount of the dialkoxysilane compound [3] and the nonaqueous organic solvent are first put into a reactor so that the dialkoxysilane compound [3] is dissolved in the nonaqueous organic solvent. Then, a predetermined amount of the chlorosilane compound [9-1] is added to the resulting solution while stirring the solution at about 0 to 10° C. Although there is no particular limitation on the technique for addition of the chlorosilane compound [9-1], it is preferable to add the chlorosilane compound [9-1] by dropping. After the completion of the addition, the solution is reacted by stirring at 0° C. to room temperature for 0.5 to 18 hours. The component (A) is obtained by termination of the reaction.

There is no particular limitation on the amounts of the hydrolysis condensate [I] and the chlorosilane compound [9-1] used in the first method. In view of the physical properties of the component (A), it is preferable to use 0.2 to 10 mmol of the chlorosilane compound [9-1] relative to 1 g of the hydrolysis condensate [I].

There is no particular limitation on the kind of the nonaqueous organic solvent used in the first method as long as the nonaqueous organic solvent does not interfere with the reaction for the formation of the component (A). Among others, an aromatic hydrocarbon or an ether is preferred as the nonaqueous organic solvent. Specific examples of the nonaqueous organic solvent include, but are not limited to, toluene, diethyl ether, tetrahydrofuran and diisopropyl ether. The amount of the nonaqueous organic solvent used is preferably 50 to 1000 mass %, more preferably 300 to 700 mass %, relative to 1 g of the hydrolysis condensate [I].

There is no particular limitation on the technique for termination of the reaction in the first method. In general, the reaction is terminated with the addition of water (preferably ion-exchanged water) to the reaction system. After the reaction, it is preferable to separate the component (A) by purification from the reaction system for ease of handling of the component (A). There is no particular limitation on the technique for separation and purification of the component (A). For example, the component (A) is separated and purified by extraction and, more specifically, extracting the organic layer from the reaction solution after the reaction. The extracted organic layer is washed with an acid and further washed with water. Then, water is removed from the washed organic layer with the addition of a drying agent. The component (A) is obtained with high purity by taking the drying agent out of the organic layer and removing the nonaqueous organic solvent under reduced pressure. Alternatively, the nonaqueous organic solvent and water may simultaneously be removed under reduced pressure without using the drying agent. After the above separation operation, it is preferable to further remove water from the component (A) by heating and stirring under reduced pressure in the presence of no solvent. At this time, the heating temperature is not particularly limited and is generally 100 to 130° C.

(Second Method)

In the second method, a predetermined amount of the hydrolysis condensate [I], the nonaqueous organic solvent and optionally the alcoholic solvent are first put into a reactor so that the hydrolysis condensate [1] is dissolved in the solvent. A predetermined amount of the silanol compound [9-2], the monoalkoxysilane compound [9-3] or the disiloxane compound [9-4] is then added to the resulting solution, followed by adding thereto the catalyst for accelerating the hydrolysis and dehydration condensation reaction. The reaction system is reacted by stirring at room temperature for 1 to 48 hours. The component (A) is obtained by termination of the reaction.

There is no particular limitation on the amounts of the hydrolysis condensate [I] and the silanol compound [9-2], monoalkoxysilane compound [9-3] or disiloxane compound [9-4] used in the second method. In view of the physical properties of the component (A), it is preferable to use the silanol compound [9-2], monoalkoxysilane compound [9-3] or disiloxane compound [9-4] in such an amount as to provide 0.2 to 10 mmol of SiH group relative to 1 g of the hydrolysis condensate [I].

There is no particular limitation on the kind of the nonaqueous organic solvent used in the second method as long as the nonaqueous organic solvent does not interfere with the reaction for the formation of the component (A). Among others, an aromatic hydrocarbon or an ether is preferred as the nonaqueous organic solvent. Specific examples of the nonaqueous organic solvent include, but are not limited to, toluene, diethyl ether, tetrahydrofuran and diisopropyl ether. The amount of the nonaqueous organic solvent used is preferably 50 to 1000 mass %, more preferably 100 to 500 mass %, relative to 1 g of the hydrolysis condensate [I].

There is also no particular limitation on the kind of the alcoholic solvent used in the second method as long as the alcoholic solvent does not interfere with the reaction for the formation of the component (A). Among others, a C₁-C₄ alcohol is preferred as the alcoholic solvent. Specific examples of the alcoholic solvent include, but are not limited to, methanol, ethanol, 1-propanol, 2-propanol and butanol. The amount of the alcoholic solvent used is preferably 10 to 500 mass %, more preferably 50 to 300 mass %, relative to 1 g of the hydrolysis condensate [I].

In the second method, the mixed solvent of the nonaqueous organic solvent and the alcoholic solvent may preferably be used depending on the kind of the catalyst used.

In the case of using a protonic acid catalyst, the use of such a mixed solvent leads to improvement in reactivity.

There is no particular limitation on the kind of the catalyst used in the second method as long as the catalyst has the function of accelerating the reaction for the formation of the component (A). Among others, an inorganic acid is preferred as the catalyst. Specific examples of the catalyst include, but are not limited to, nitric acid, hydrochloric acid and sulfuric acid. The amount of the catalyst used is preferably 0.0001 to 10 mmol %, more preferably 0.05 to 5 mmol %, relative to 1 g of the hydrolysis condensate [I].

There is no particular limitation on the technique for termination of the reaction in the second method. In general, the reaction is terminated with the addition of water (preferably ion-exchanged water) to the reaction system. After the reaction, it is preferable to separate the component (A) by purification from the reaction system for ease of handling of the component (A). There is no particular limitation on the technique for separation and purification of the component (A). For example, the component (A) is separated and purified by extraction and, more specifically, extracting the organic layer from the reaction solution after the reaction. The extracted organic layer is washed with water (preferably ion-exchanged water). Then, water is removed from the washed organic layer with the addition of a drying agent. The component (A) is obtained with high purity by taking the drying agent out of the organic layer and removing the nonaqueous organic solvent under reduced pressure. Alternatively, the nonaqueous organic solvent and water may simultaneously be removed under reduced pressure without using the drying agent. After the above separation operation, it is preferable to further remove water from the component (A) by heating and stirring under reduced pressure in the presence of no solvent. At this time, the heating temperature is not particularly limited and is generally 100 to 130° C.

(Formation of Component (B))

There is no particular limitation on the method for formation of the component (B). For example, the component (B) is formed by reacting a product of hydrolysis and condensation of a dialkoxysilane compound of the following general formula [6], a trialkoxysilane compound of the following general formula [7] and a tetraalkoxysilane compound of the following general formula [8] (sometimes referred to as “hydrolysis condensate [II]”) with a vinylsilane compound of the following general formula [10-1], [10-2], [10-3] or [10-4].

R⁵₂Si(OR¹⁰)₂ [6]

R⁶Si(OR¹¹)₃ [7]

Si(OR¹²)₄ [8]

In the general formula [6], R⁵ has the same meaning as in the formula [2]; R¹⁰ is each independently a C₁-C₃ alkyl group; and two R¹⁰ may be of the same kind or different kinds. In the general formula [7], R⁶ has the same meaning as in the formula [2]; R¹¹ is each independently a C₁-C₃ alkyl group; and three R¹¹ may be of the same kind or different kinds. In the general formula [8], R¹² is each independently a C₁-C₃ alkyl group; and four R¹² may be of the same kind or different kinds.

CH₂═CH—SiR⁴₂Cl [10-1]

CH₂═CH—SiR⁴₂(OH) [10-2]

CH₂═CH—SiR⁴₂(OR¹⁴) [10-3]

(CH₂═CH—SiR⁴₂)₂O [10-4]

In the general formulas [10-1], [10-2], [10-3] and [10-4], R⁴ has the same meaning as in the formula [2]. In the general formula [10-3], R¹⁴ is a C₁-C₃ alkyl group.

Hereinafter, the dialkoxysilane compound of the general formula [6], the trialkoxysilane compound of the general formula [7] and the tetraalkoxysilane compound of the general formula [8] are sometimes referred to as “dialkoxysilane compound [6]”, “trialkoxysilane compound [7]” and “tetraalkoxysilane compound [8]”, respectively. Further, the vinylsilane compounds of the general formulas [10-1], [10-2], [10-3] and [10-4] are sometimes referred to as “chlorovinylsilane compound [10-1]”, “vinylsilanol compound [10-2]”, “monoalkoxyvinylsilane compound [10-3]” and “divinyldisiloxane compound [10-4]”, respectively. The vinylsilane compounds of the general formulas [10-1], [10-2], [10-3] and [10-4] may be generically called “vinylsilane compound [10]” without being distinguished from each other.

Specific examples of the dialkoxysilane compound [6] include, but are not limited to, dimethyldimethoxysilane, dimethyldiethoxysilane, ethyldiethoxysilane, diethyldimethoxysilane and diethyldiethoxysilane. Among others, dimethyldimethoxysilane and dimethyldiethoxysilane are preferred.

Specific examples of the trialkoxysilane compound [7] include, but are not limited to, methyltrimethoxysilane, methyltriethoxysilane, ethyltrimethoxysilane, ethyltriethoxysilane, vinyltrimethoxysilane, vinyltriethoxysilane, phenyltrimethoxysilane, phenyltriethoxysilane, 3-(trifluoromethyl)phenyltrimethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane, 3,5-(ditrifluoromethyl)phenyltriethoxysilane, naphthyltrimethoxysilane and naphthyltriethoxysilane. Among others, methyltrimethoxysilane, methyltriethoxysilane, phenyltrimethoxysilane, phenyltriethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane and 3,5-(ditrifluoromethyl)phenyltriethoxysilane are preferred. Particularly preferred are methyltrimethoxysilane, methyltriethoxysilane, phenyltrimethoxysilane and phenyltriethoxysilane.

Specific examples of the tetraalkoxysilane compound [8] include, but are not limited to, tetramethoxysilane, tetraethoxysilane, tetra-n-propoxysilane and tetraisopropoxysilane. Among others, tetramethoxysilane and tetraethoxysilane are preferred.

There is no particular limitation on the combination of the dialkoxysilane compound [6], the trialkoxysilane compound [7] and the tetraalkoxysilane compound [8] used for the preparation of the component (B). Each of the dialkoxysilane compound [6], the trialkoxysilane compound [7] and the tetraalkoxysilane compound [8] can be of one kind or can be a combination of two or more kinds. It is preferable to use, in combination, one or more selected from the group consisting of dimethyldimethoxysilane, dimethyldiethoxysilane, diethyldimethoxysilane and diethyldiethoxysilane as the dialkoxysilane compound [6], one or more selected from the group consisting of methyltrimethoxysilane, methyltriethoxysilane, ethyltrimethoxysilane, ethyltriethoxysilane, phenyltrimethoxysilane, phenyltriethoxysilane, 3-(trifluoromethyl)phenyltriethoxysilane, 4-(trifluoromethyl)phenyltrimethoxysilane, 4-(trifluoromethyl)phenyltriethoxysilane, 3,5-(ditrifluoromethyl)phenyltrimethoxysilane and 3,5-(ditrifluoromethyl)phenyltriethoxysilane as the trialkoxysilane compound [7], and one or more selected from the group consisting of tetramethoxysilane, tetraethoxysilane and tetraisopropoxysilane as the tetraalkoxysilane compound [8]. It is particularly preferable to use, in combination, one or more selected from the group consisting of dimethyldimethoxysilane and dimethyldiethoxysilane as the dialkoxysilane compound [6], one or more selected from the group consisting of methyltrimethoxysilane, methyltriethoxysilane, phenyltrimethoxysilane and phenyltriethoxysilane as the trialkoxysilane compound [7], and one or more selected from the group consisting of tetramethoxysilane and tetraethoxysilane as the tetraalkoxysilane compound [8].

Specific examples of the chlorovinylsilane compound [10-1] include, but are not limited to, chlorodimethylvinylsilane and chlorodiethylvinylsilane. Among others, chlorodimethylvinylsilane is preferred.

Specific examples of the vinylsilanol compound [10-2] include, but are not limited to, dimethylvinylsilanol and diethylvinylsilanol. Among others, dimethylvinylsilanol is preferred.

Specific examples of the monoalkoxyvinylsilane compound [10-3] include, but are not limited to, dimethylmethoxyvinylsilane, dimethylethoxyvinylsilane, diethylmethoxyvinylsilane and diethylethoxyvinyl silane. Among others, dimethylmethoxyvinylsilane and dimethylethoxyvinylsilane are preferred.

Specific examples of the divinyldisiloxane compound [10-4] include, but are not limited to, 1,1,3,3-tetramethyl-1,3-divinyldisiloxane and 1,1,3,3-tetraethyl-1,3-divinyldisiloxane. Among others, 1,1,3,3-tetramethyl-1,3-divinyldisiloxane is preferred.

The hydrolysis condensate [II] can be produced in the same manner as the above-explained method for production of the hydrolysis condensate [I] by replacing the dialkoxysilane, trialkoxysilane and tetraalkoxysilane compounds [3], [4] and [5] with the dialkoxysilane, trialkoxysilane and tetraalkoxysilane compounds [6], [7] and [8], respectively, and replacing the hydrolysis condensate [I] with the hydrolysis condensate [II].

The method for formation of the component (B) by reaction of the hydrolysis condensate [II] and the vinylsilane compound [10] will be next explained below. The component (B) can be formed in the same manner as the above-explained method for formation of the component (A) from the hydrolysis condensate [I] by replacing the silane compound [9] with the vinylsilane compound [10], replacing the chlorosilane, silanol, monoalkoxysilane and disiloxane compounds [9-1], [9-2], [9-3] and [9-4] with the chlorovinylsilane, vinylsilanol, monoalkoxyvinylsilane and divinyldisiloxane compounds [10-1], [10-2], [10-3] and [10-4], respectively, and replacing SiH group, the hydrolysis condensate [I] and the component (A) with Si—CH═CH₂ group, the hydrolysis condensate [II] and the component (B), respectively.

[Preparation of Component (C)]

The component (C) can be provided as a commercially available product or can be formed by a conventionally known method.

[Cured Product of Curable Silicone Resin Composition]

The cured product of the present invention is obtained by heating the composition of the present invention.

The cured product of the present invention is usable as an encapsulant of a semiconductor device. The cured product of the present invention is particularly suitable as an encapsulant of an optical semiconductor device or power semiconductor device. As the encapsulant of the optical semiconductor device, the cured product of the present invention can suitably be used to encapsulate an optical element of LED or semiconductor laser.

In general, the light extraction efficiency of optical semiconductor devices has been improved by various techniques. However, the use of low-transparency semiconductor encapsulants leads to deterioration in the light extraction efficiency of optical semiconductor devices. It thus tends to be difficult to obtain the optical semiconductor devices with high brightness. In addition, the amount of energy corresponding to such light extraction efficiency deterioration turns into heat, which can unfavorably cause thermal degradation of the optical semiconductor devices.

The cured product of the present invention shows good transparency. More specifically, the cured product of the present invention has good light transmittance in the wavelength range of generally 300 nm or longer, preferably 350 nm or longer, and generally 900 nm or shorter, preferably 500 nm or shorter. It is thus preferable to use the cured product of the present invention as the encapsulant of the optical semiconductor device whose light emission wavelength is in the above range so that the optical semiconductor device can ensure high brightness. The use of the cured product of the present invention is however not limited to the encapsulant of the optical semiconductor device whose light emission wavelength is in the above range. The light transmittance can be determined by transmittance measurement with the use of an ultraviolet-visible spectrophotometer.

The cured product of the present invention also shows good heat resistant transparency. In other words, the cured product of the present invention is less likely to cause variations in the transmittance for light of given wavelength even when exposed to high-temperature conditions for a long term. More specifically, the cured product of the present invention has good light transmittance retention rate, before and after exposure at 200° C. for 100 hours, in the wavelength range of generally 300 nm or longer, preferably 350 nm or longer, and generally 900 nm or shorter, preferably 500 nm or shorter. It is thus preferable to use the cured product of the present invention as the encapsulant of the optical semiconductor device whose light emission wavelength is in the above range such that the optical semiconductor device can ensure high brightness. The use of the cured product of the present invention is however not limited to the encapsulant of the optical semiconductor device whose light emission wavelength is in the above range. The light transmittance variations can be determined by transmittance measurement with the use of an ultraviolet-visible spectrophotometer.

There is no particular limitation on the method for curing the composition of the present invention. For example, it is feasible to apply the composition of the present invention to a target part of the encapsulation target such as LED by injection, dropping, flow expansion, casting, extrusion etc., or mold the composition of the present invention integrally with the encapsulation target by transfer molding, injection molding, and then, cure the composition by heating such that the encapsulation target can be encapsulated with the cured product. The heating temperature is generally 45 to 300° C., preferably 60 to 200° C. When the heating temperature is 45° C. or higher, it is unlikely that adhesion of the cured product will be observed. When the heating temperature is 300° C. or lower, it is unlikely that there will be observed air bubbles in the cured product. It is thus practical to heat the composition in such a temperature range. The heating time is not particularly limited and is generally 0.5 to 2 hours, preferably 1 to 10 hours. When the heating time is 0.5 hour or longer, the curing reaction proceeds sufficiently. In the case of use for LED encapsulation etc. where accuracy is required, it is preferable to set the curing time long.

[Encapsulant]

The cured product of the present invention is usable as an encapsulant of a semiconductor device and is particularly suitable as an encapsulant of an optical semiconductor device or power semiconductor device. As mentioned above, the encapsulant using the cured product of the present invention shows good heat resistant transparency. The encapsulant using the cured product of the present invention also shows good heat resistance, cold resistance and electrical insulating property as in the case of cured products of conventional addition curable silicone resin compositions

[Optical Semiconductor Device]

An optical semiconductor device of the present invention has at least an optical semiconductor element sealed by the cured product of the present invention. There is no particular limitation on the other configurations of the optical semiconductor device of the present invention. The optical semiconductor device of the present invention may have any device element or elements other than the optical semiconductor element. Examples of the other device element include a base substrate, a lead wire, a wiring wire, a control element, an insulating substrate, a reflector plate, a heat sink, a conductor, a die bonding material and a bonding pad. Not only the optical semiconductor element but also a part or all of the device element may be encapsulated by the cured product of the present invention.

Examples of the optical semiconductor device of the present invention include, but are not limited to, a light-emitting diode (LED), a semiconductor laser device and a photocoupler. The optical semiconductor device of the present invention is suitably usable as: backlights of liquid crystal displays; lighting equipment; light sources of various sensors, printers and copiers; light sources of automotive measurement instruments; signal lights; indicator lights; monitors; light sources of planar light emitters; displays; decoration equipment; various lights; switching devices; and the like.

One example of the optical semiconductor device of the present invention is shown in FIG. 1. As shown in FIG. 10, the optical semiconductor device 10 includes at least an encapsulant 1, an optical semiconductor element 2 and a bonding wire 3 mounted on an optical semiconductor substrate 6. The optical semiconductor substrate 6 has a recess, with a bottom of the recess defined by a leadframe 5 and an inner circumferential surface of the recess defined by a reflector member 4.

The optical semiconductor element 2 is coupled to the lead frame 5 by a die bonding material (not shown). A bonding pad (not shown) on the optical semiconductor element 2 is electrically connected to the leadframe 5 by the bonding wire 3. The reflector member 4 is arranged to reflect light of the optical semiconductor element 2 to a predetermined direction. The encapsulant 1 is placed into the recess of the optical semiconductor substrate 6 so as to encapsulate at least the optical semiconductor element 2. The bonding wire 3 may also be encapsulated by the encapsulant 1. The encapsulant 1 is formed from the composition of the present invention. As mentioned above, the phosphor (not shown) may be contained in the inside of the encapsulant 1. By this encapsulant 1, it is possible to protect the optical semiconductor element 2 from moisture, dust etc. and maintains the reliability of the optical semiconductor element 2 for a long term. In the case where the bonding wire 3 is also encapsulated by the encapsulant 1, it is possible to prevent any electrical malfunction caused by disconnection, breakage, short circuit etc. of the bonding wire 3.

The cured product of the present invention is also usable as a semiconductor bonding material as will be explained later. It is thus feasible to use the cured product of the present invention as the above-mentioned die bonding material.

Examples of the optical semiconductor element 2 encapsulated by the encapsulant 1 in the optical semiconductor device 10 include LED, a semiconductor laser, a photo diode, a photo transistor, a solar battery, CCD (charge coupled element) and the like. Herein, FIG. 1 merely shows one example of the optical semiconductor device of the present invention. The configurations of the reflector member and the leadframe and the mounting structure of the optical semiconductor can be modified as appropriate.

There is no particular limitation on the method for manufacturing the optical semiconductor device 10 of FIG. 1. For example, the optical semiconductor device can be manufactured as follows. The optical semiconductor element 2 is first wire bonded to the leadframe 5 with the reflector member 4. Then, the optical semiconductor element 2 and the leadframe 5 are wire bonded to each other by the bonding wire 3. The encapsulant 1 is subsequently formed by introducing the composition of the present invention into the inside of the reflector member around the optical semiconductor element (i.e. the recess defined by the leadframe and the reflector member) and curing the composition by heating at 50 to 250° C.

[Semiconductor Bonding Material]

The composition of the present invention shows good adhesion and thus is usable as a semiconductor bonding material. For example, the composition of the present invention can be used for bonding of a semiconductor element and a package, bonding of a semiconductor element and a sub mount, bonding of package components, bonding of a semiconductor device and an external optical member and the like by application, printing, potting etc. Since the composition of the present invention shows good heat resistance, it is feasible to use the composition of the present invention as a bonding material of a high-output optical semiconductor device, which is exposed to high temperatures and ultraviolet radiation for a long term, such that the optical semiconductor device can ensure long-term operation reliability.

### EXAMPLES

The present invention will be described in more detail below by way of the following examples. It should be however noted that the following examples are not intended to limit the present invention thereto.

In the following synthesis examples and comparative synthesis examples, silicone resins were synthesized. The physical properties of the respective silicone resins were measured and evaluated according to the following methods.

[Quantification of SiH Group and Si—CH═CH₂ Group]

Into a 6-mL sample tube, 20 to 30 mg of the silicone resin was put. Further, 0.8 mL of deuterated dichloromethane was put into the sample tube so that the silicone resin was dissolved in the deuterated dichloromethane. To this solution, 2.0 μL (0.0282 mmol) of dimethyl sulfoxide was added. After the sample tube was closed, the solution was stirred uniformly. The resulting solution was taken as a measurement sample and measured by ¹H-NMR. Based on the measurement results, the proton ratio of dimethyl sulfoxide and the proton ratio of H—Si group or CH₂═CH—Si group were determined. The mole number of H—Si group or CH₂═CH—Si group in the sample was calculated from the proton ratio determination results. Then, the amount of each functional group in 1 g of the sample was determined according to the following equation.

Mole number of functional group in silicon resin (mmol)/Amount of sample (g)×1000=Amount of functional group in 1 g of sample (mmol)

The ¹H-NMR measurement of the silicone resin was conducted with the use of a 400-MHz nuclear magnetic resonance spectrometer (manufactured by JEOL Ltd., model: ECA-400).

The chemical shifts of the respective functional groups of the silicone resin are indicated below.

### Me-Si: 0.0 to 0.5 ppm (3H)

### H—Si: 4.0 to 5.0 ppm (1H)

### CH₂═CH: 5.5 to 6.5 ppm (3H)

### Ph-Si: 7.0 to 8.0 ppm (5H)

[Quantification of Toluene]

Into a 6-mL sample tube, 20 to 30 mg of the silicone resin was put. Further, 0.8 mL of deuterated dichloromethane was put into the sample tube so that the silicone resin was dissolved in the deuterated dichloromethane. After the sample tube was closed, the solution was stirred uniformly. The resulting solution was taken as a measurement sample and measured by ¹H-NMR. Based on the measurement results, the proton ratio of Me group and Ph group in the silicone resin and the proton ratio of Me group in toluene were determined. The amount of toluene in the sample was calculated from the proton ratio determination results. Then, the amount of toluene in the silicone resin was determined according to the following equation.

(Molecular weight of toluene (mol/g)×Area of Me (toluene)/3)/(Molecular weight of PhSiO_{1.5} (mol))×(Area of Ph−(Area of Me (toluene)×5/3))/5+((Molecular weight of Me₂SiO (mol/g)×Area of Me×6)+(Molecular weight of toluene (mol/g)×Area of Me (toluene)/3))=Amount of toluene (wt %)

The ¹H-NMR measurement of the silicone resin was conducted with the use of a 400-MHz nuclear magnetic resonance spectrometer (manufactured by JEOL Ltd., model: ECA-400).

The chemical shifts of the respective functional groups of the silicone resin are indicated below.

### Me: 0.0 to 0.5 ppm (3H)

Me (toluene): 2.2 to 2.4 ppm (3H)

### Ph: 7.0 to 8.0 ppm (5H)

[Quantification of HO—Si Group]

To 200 mg of the silicone resin, 0.5 mL of deuterated dichloromethane was added so that the silicone resin was dissolved in the deuterated dichloromethane. To this solution, 10 mg of acetylacetone chromium(III) was added as a releasing agent. The resulting solution was measured by ²⁹Si-NMR. The detected signals were classified as peaks (a) to (p) as indicated in TABLE 1. The areas of the respective peaks were determined in percentages (integral ratios) on the basis of the sum of the integral areas of all the peaks.

The ²⁹Si-NMR measurement of the silicone resin was conducted with the use of a 400-MHz nuclear magnetic resonance spectrometer (manufactured by JEOL Ltd., model: JNM-AL400).

TABLE 1

| | | Molecular weight | Chemical shift | |
|---|---|---|---|---|
| Peak | Structure | (g/mol) | (²⁹Si-NMR) | |
| (a) | Me₂(OH)SiO_{1/2} | 83.16 | −5 to −15 | ppm |
| (b) | Me₂SiO_{1/2} | 74.15 | −15 to −25 | ppm |
| (c) | Ph(OH)₂SiO_{1/2} | 147.2 | −55 to −65 | ppm |
| (d) | Ph(OH)SiO_{2/2} | 138.2 | −65 to −75 | ppm |
| (e) | PhSiO_{3/2} | 129.2 | −75 to −80 | ppm |
| (f) | Si(OH)₂O_{2/2} | 78.10 | −85 to −90 | ppm |
| (g) | Si(OH)O_{3/2} | 69.09 | −95 to −105 | ppm |
| (h) | SiO_{4/2} | 60.08 | −105 to −115 | ppm |
| (i) | H(Me)₂SiO_{1/2} | 67.16 | 0 to −5 | ppm |
| (j) | CH₂═CH(Me)₂SiO_{1/2} | 93.20 | −5 to −10 | ppm |
| (k) | H(OH)₂SiO_{1/2} | 71.11 | −60 to −65 | ppm |
| (i) | H(OH)SiO_{2/2} | 62.10 | −70 to −80 | ppm |
| (m) | HSiO_{3/2} | 53.09 | −80 to −90 | ppm |
| (n) | CH₂═CH(OH)₂SiO_{1/2} | 97.15 | −60 to −65 | ppm |
| (o) | CH₂═CH(OH)SiO_{2/2} | 88.14 | −65 to −75 | ppm |
| (p) | CH₂═CH—SiO_{3/2} | 79.13 | −75 to −80 | ppm |

(H—SiR¹₂O_{1/2})ₐ(SiR²₂O_{2/2})_{b}(R³SiO_{3/2})ₑ(SiO_{4/2})_{d} [1]

The numbers a, b, c and d of the formula [1] were determined according to the following equations, respectively.

a=Area of peak (i)/Sum of areas of all peaks

b=(Area of peak (a)+Area of peak (b))/Sum of areas of all peaks

c=(Area of peak (c)+Area of peak (d)+Area of peak (e))/Sum of areas of all peaks

d=(Area of peak (f)+Area of peak (g)+Area of peak (h))/Sum of areas of all peaks

(CH₂═CH—SiR⁴₂O_{1/2})ₑ(SiR⁵₂O_{2/2})_{f}(R⁶SiO_{3/2})_{g}(SiO_{4/2})ₕ [2]

The numbers e, f g and h of the formula [2] were determined according to the following equations, respectively.

e=Area of peak (j)/Sum of areas of all peaks

f=(Area of peak (a)+Area of peak (b))/Sum of areas of all peaks

g=(Area of peak (c)+Area of peak (d)+Area of peak (e))/Sum of areas of all peaks

h=(Area of peak (f)+Area of peak (g)+Area of peak (h))/Sum of areas of all peaks

In the case where there was overlap between the peaks of Me-Si group, Ph-Si group, H—Si group, CH₂═CH—Si group and the other group in the ²⁹Si-NMR spectrum, the integral ratios were determined based on the integral areas of the peaks of Me-Si group, Ph-Si group, H—Si group, CH₂═CH—Si group and the other group in the ¹H-NMR spectrum.

Further, the composition ratios of the respective silicone resins (DA1) and (DB1) obtained in Comparative Synthesis Examples were determined according to the following equations.

Composition ratio of (H—SiO_{3/2}) (Area of peak (k)+Area of peak (l)+Area of peak (m))/Sum of area of all peaks

Composition ratio of (CH₂═CHSiO_{3/2})=(Area of peak (n)+Area of peak (o)+Area of peak (p))/Sum of area of all peaks

The amount of HO—Si group (mmol/g) was then determined based on the above-obtained integral ratios.

[A]=Integral ratio of peak (a)+2×Integral ratio of peak (c)+Integral ratio of peak (d)+2×Integral ratio of peak (f)+Integral ratio of peak (g)+2×Integral ratio of peak (k)+Integral ratio of peak (l)+2×Integral ratio of peak (n)+Integral ratio of peak (o)

[B]=Integral ratio of peak (a)×83.16+Integral ratio of peak (b)×74.15+Integral ratio of peak (c)×147.2+Integral ratio of peak (d)×138.2+Integral ratio of peak (e)×129.2+Integral ratio of peak (f)×78.10+Integral ratio of peak (g)×69.09+Integral ratio of peak (h)×60.08+Integral ratio of peak (i)×67.16+Integral ratio of peak (j)×93.20+Integral ratio of peak (k)×71.11+Integral ratio of peak (l)×62.10+Integral ratio of peak (m)×53.09+Integral ratio of peak (n)×97.15+Integral ratio of peak (o)×88.14+Integral ratio of peak (p)×79.13

Amount of HO—OH group (mmol/g)=([A]/[B])×1000

In the case where the peaks (i) and (j) overlapped the peak (a) in the ²⁹Si-NMR spectrum, the integral ratio of the peak (a) was determined by determining the integral ratios in percentages of the peaks of Ph-Si group, H—Si group, CH₂═CH—Si group and, if found, the other group in the ¹H-NMR spectrum, determining the sum of the integral ratios of the ¹H-NMR spectrum peaks (c), (d) and (e), determining the integral ratios of the ²⁹Si-NMR spectrum peaks (i) and (j) based on the integral ratios of the ¹H-NMR spectrum peaks, and then, subtracting the integral ratios of the peaks (i) and (j) from the total integral ratio of the overlapped peaks (a), (i) and (j). In the other cases, if ²⁹Si-NMR spectrum peaks overlapped the above-mentioned peaks, the integral ratios were determined from the ¹H-NMR spectrum data in the same method as above.

[Measurement of Mass-Average Molecular Weight (Mw)]

The mass-average molecular weight (Mw) of the silicone resin was determined by gel permeation chromatography (abbreviation: GPC) under the following conditions on the basis of a calibration curve using polystyrene as a standard material.

Chromatograph: manufactured by Tosoh Corporation, model: HLC-8320GPC
Column: manufactured by Tosoh Corporation, trade name: TSK gel Super HZ 2000×4, 3000×2
Eluent: tetrahydrofuran

In the case of the silicone resin having a mass-average molecular weight (Mw) exceeding 1500, the mass-average molecular weight (Mw) of the silicone resin was determined by gel permeation chromatography (abbreviation: GPC) under the following conditions on the basis of a calibration curve using polystyrene as a standard material.

Chromatograph: manufactured by Tosoh Corporation, model: HLC-8320GPC
Column: manufactured by Tosoh Corporation, trade name: TSK gel Super HZM-H x 2
Eluent: tetrahydrofuran

[Measurement of Refractive Index]

The refractive index of the silicone resin was measured with a refractometer (manufactured by Kyoto Electronics Manufacturing Co., Ltd., model: RA-600).

[Measurement of Viscosity]

The viscosity of the silicone resin was measured at 25° C. with a rotating viscometer (manufactured by Brookfield Engineering Laboratories Inc., model: DV-II+PRO) in combination with a temperature control unit (manufactured by Brookfield Engineering Laboratories Inc., model: THERMOSEL).

### Synthesis Example 1-1

<Synthesis of Silicone Resin (I-1)>

Into a 2-L three-neck flask with an agitation blade of fluororesin and a Dimroth condenser, 120.2 g (1.0 mol) of Me₂Si(OMe)₂ and 198.3 g (1.0 mol) of PhSi(OMe)₃ were put. Subsequently, 239.6 g of 2-propanol, 185.0 g of water and 0.12 g of acetic acid were put into the flask. The inside of the flask was kept heated at 100° C. continuously for 6 hours while stirring and thereby subjected to hydrolysis and condensation. After that, the thus-obtained reaction solution was returned to room temperature. The reaction solution was put into a 2-L separatory funnel and separated into two layers with the addition of 400 mL of toluene and 400 mL of water. The aqueous layer was removed. The organic layer was washed twice with 400 mL of water and recovered. Then, toluene was distilled from the organic layer by an evaporator under reduced pressure. As a result, silicone resin (I-1) was obtained as a colorless viscous liquid.

The yield of the silicone resin (I-1) was 160.8 g. The silicone resin (I-1) had a mass-average molecular weight (Mw) of 1,000 and a composition ratio of (Me₂SiO_{2/2})_{0.43}(PhSiO_{3/2})_{0.57}. The amount of HO—Si group in the silicone resin (I-1) was 7.8 mmol/g (13 mass %).

### Synthesis Example 1-2

<Synthesis of Silicone Resin (A1)>

Into a flask, 39.7 g of the silicone resin (I-1), 119 g of toluene, 39.7 g of methanol, 8.3 g of 1,1,3,3-tetramethyldisiloxane and 0.20 mL of 70% concentrated nitric acid were put. The resulting solution was stirred at room temperature. After a lapse of 4 hours, the thus-obtained reaction solution was put into a separatory funnel and subjected to extraction with 119 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A1) was obtained as a colorless transparent viscous liquid.

The yield of the silicone resin (A1) was 42.4 g. The silicone resin (A1) had a mass-average molecular weight (Mw) of 1,900, a viscosity of 200 cP and a composition ratio of (Me₂SiO_{2/2})_{0.31}(PhSiO_{3/2})_{0.42}(H(Me)₂SiO_{1/2})_{0.27}. The amount of H—Si group in the silicone resin (A1) was 2.8 mmol/g. The amount of HO—Si group in the silicone resin (A1) was 2.0 mmol/g (3.4 mass %).

### Synthesis Example 1-3

<Synthesis of Silicone Resin (B1)>

Into a flask, 19.9 g of the silicone resin (I-1), 59.7 g of toluene, 19.9 g of methanol, 5.76 g of 1,3-divinyl-1,1,3,3-tetramethyldisiloxane and 1.98 mL of 70% concentrated nitric acid were put. The resulting solution was stirred at room temperature. After a lapse of 4 hours, the thus-obtained reaction solution was put into a separatory funnel and subjected to extraction with 59.7 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B1) was obtained as a colorless transparent viscous liquid.

The yield of the silicone resin (B1) was 20.6 g. The silicone resin (B1) had a mass-average molecular weight (Mw) of 1,800, a viscosity of 350 cP and a composition ratio of (Me₂SiO_{2/2})_{0.32}(PhSiO_{3/2})_{0.45}(CH₂═CH(Me)₂SiO_{1/2})_{0.23}. The amount of CH₂═CH—Si group in the silicone resin (B1) was 2.3 mmol/g. The amount of HO—Si group in the silicone resin (B1) was 2.1 mmol/g (3.6 mass %).

### Synthesis Example 2-1

<Synthesis of Silicone Resin (1-2)>

The same reaction process as in Synthesis Example 1-1 was performed except that: 198.3 g (0.95 mol) of Me₂Si(OMe)₂, 188.4 g (0.95 mol) of PhSi(OMe)₃ and 13.0 g (0.063 mol) of Si(OEt)₄ were used in place of 120.2 g (1.0 mol) of Me₂Si(OMe)₂ and 198.3 g (1.0 mol) of PhSi(OMe)₃. As a result, silicone resin (1-2) was obtained as a colorless viscous liquid.

The yield of the silicone resin (1-2) was 163.0 g. The silicone resin (1-2) had a mass-average molecular weight (Mw) of 900 and a composition ratio of (Me₂SiO_{2/2})_{0.41}(PhSiO_{3/2})_{0.52}(SiO_{4/2})_{0.06}. The amount of HO—Si group in the silicone resin (1-2) was 8.5 mmol/g (14 mass %).

### Synthesis Example 2-2

<Synthesis of Silicone Resin (A2)>

Into a flask, 55.8 g of the silicone resin (1-2), 167.4 g of toluene, 55.8 g of methanol, 12.7 g of 1,1,3,3-tetramethyldisiloxane and 0.30 mL of 70% concentrated nitric acid were put. The resulting solution was stirred at room temperature. After a lapse of 4 hours, the thus-obtained reaction solution was put into a separatory funnel and subjected to extraction with 167.4 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A2) was obtained as a colorless transparent viscous liquid.

The yield of the silicone resin (A2) was 55.1 g. The silicone resin (A2) had a mass-average molecular weight (Mw) of 1,000, a viscosity of 140 cP and a composition ratio of (Me₂SiO_{2/2})_{0.21}(PhSiO_{3/2})_{0.45}(SiO_{4/2})_{0.06}(H(Me)₂SiO_{1/2})_{0.28}. The amount of H—Si group in the silicone resin (A2) was 2.6 mmol/g. The amount of HO—Si group in the silicone resin (A2) was 2.9 mmol/g (4.9 mass %).

### Synthesis Example 2-3

<Synthesis of Silicone Resin (B2)>

Into a flask, 27.9 g of the silicone resin (1-2), 83.7 g of toluene, 27.9 g of methanol, 8.81 g of 1,3-divinyl-1,1,3,3-tetramethyldisiloxane and 3.03 mL of 70% concentrated nitric acid were put. The resulting solution was stirred at room temperature. After a lapse of 4 hours, the thus-obtained reaction solution was put into a separatory funnel and subjected to extraction with 83.7 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B2) was obtained as a colorless transparent viscous liquid.

The yield of the silicone resin (B2) was 29.5 g. The silicone resin (B2) had a mass-average molecular weight (Mw) of 1,100, a viscosity of 200 cP and a composition ratio of (Me₂SiO_{2/2})_{0.26}(PhSiO_{3/2})_{0.42}(SiO_{4/2})_{0.05}(CH₂═CH(Me)₂SiO_{1/2})_{0.27}. The amount of CH₂═CH—Si group in the silicone resin (B2) was 2.7 mmol/g. The amount of HO—Si group in the silicone resin (B2) was 1.7 mmol/g (2.9 mass %).

### Synthesis Example 3-1

<Synthesis of Silicone Resin (1-3)>

The same reaction process as in Synthesis Example 1-1 was performed except that: 108.2 g (0.90 mol) of Me₂Si(OMe)₂, 178.5 g (0.90 mol) of PhSi(OMe)₃ and 26.0 g (0.125 mol) of Si(OEt)₄ were used in place of 120.2 g (1.0 mol) of Me₂Si(OMe)₂ and 198.3 g (1.0 mol) of PhSi(OMe)₃. As a result, silicone resin (1-3) was obtained as a colorless transparent viscous liquid.

The yield of the silicone resin (1-3) was 154.2 g. The silicone resin (1-3) had a mass-average molecular weight (Mw) of 900 and a composition ratio of (Me₂SiO_{2/2})_{0.35}(PhSiO_{3/2})_{0.56}(SiO_{4/2})_{0.10}. The amount of HO—Si group in the silicone resin (1-3) was 8.5 mmol/g (14 mass %).

### Synthesis Example 3-2

<Synthesis of Silicone Resin (A3)>

Into a flask, 57.4 g of the silicone resin (1-3), 172.2 g of toluene, 57.4 g of methanol, 16.4 g of 1,1,3,3-tetramethyldisiloxane and 0.39 mL of 70% concentrated nitric acid were put. The resulting solution was stirred at room temperature. After a lapse of 4 hours, the thus-obtained reaction solution was put into a separatory funnel and subjected to extraction with 172.2 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A3) was obtained as a colorless transparent viscous liquid.

The yield of the silicone resin (A3) was 58.4 g. The silicone resin (A3) had a mass-average molecular weight (Mw) of 1,100, a viscosity of 180 cP and a composition ratio of (Me₂SiO_{2/2})_{0.15}(PhSiO_{3/2})_{0.46}(SiO_{4/2})_{0.07}(H(Me)₂SiO_{1/2})_{0.33}. The amount of H—Si group in the silicone resin (A3) was 3.2 mmol/g. The amount of HO—Si group in the silicone resin (A3) was 2.7 mmol/g (4.6 mass %).

### Synthesis Example 3-3

<Synthesis of Silicone Resin (B3)>

Into a flask, 28.7 g of the silicone resin (1-3), 86.1 g of toluene, 28.7 g of methanol, 11.4 g of 1,3-divinyl-1,1,3,3-tetramethyldisiloxane and 3.92 mL of 70% concentrated nitric acid were put. The resulting solution was stirred at room temperature. After a lapse of 4 hours, the thus-obtained reaction solution was put into a separatory funnel and subjected to extraction with 86.1 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B3) was obtained as a colorless transparent viscous liquid.

The yield of the silicone resin (B3) was 32.7 g. The silicone resin (B3) had a mass-average molecular weight (Mw) of 1,300, a viscosity of 230 cP and a composition ratio of (Me₂SiO_{2/2})_{0.20}(PhSiO_{3/2})_{0.43}(SiO_{4/2})_{0.07}(CH₂═CH(Me)₂SiO_{1/2})_{0.30}. The amount of CH₂═CH—Si group in the silicone resin (B3) was 2.8 mmol/g. The amount of HO—Si group in the silicone resin (B3) was 1.7 mmol/g (2.9 mass %).

### Synthesis Example 4-1

<Synthesis of Silicone Resin (1-4)>

The same reaction process as in Synthesis Example 1-1 was performed except that: 96.2 g (0.80 mol) of Me₂Si(OMe)₂, 158.6 g (0.80 mol) of PhSi(OMe)₃ and 52.1 g (0.25 mol) of Si(OEt)₄ were used in place of 120.2 g (1.0 mol) of Me₂Si(OMe)₂ and 198.3 g (1.0 mol) of PhSi(OMe)₃. As a result, silicone resin (1-4) was obtained as a colorless transparent viscous liquid.

The yield of the silicone resin (1-4) was 143.4 g. The silicone resin (1-4) had a mass-average molecular weight (Mw) of 1,100 and a composition ratio of (Me₂SiO_{2/2})_{0.34}(PhSiO_{3/2})_{0.51}(SiO_{4/2})_{0.15}. The amount of HO—Si group in the silicone resin (1-4) was 7.7 mmol/g (13 mass %).

### Synthesis Example 4-2

<Synthesis of Silicone Resin (A4)>

Into a flask, 173.7 g of the silicone resin (1-4), 521.1 g of toluene, 173.7 g of methanol, 31.4 g of 1,1,3,3-tetramethyldisiloxane and 0.75 mL of 70% concentrated nitric acid were put. The resulting solution was stirred at room temperature. After a lapse of 4 hours, the thus-obtained reaction solution was put into a separatory funnel and subjected to extraction with 521.1 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A4) was obtained as a colorless transparent viscous liquid.

The yield of the silicone resin (A4) was 165.7 g. The silicone resin (A4) had a mass-average molecular weight (Mw) of 1,500, a viscosity of 4,000 cP and a composition ratio of (Me₂SiO_{2/2})_{0.16}(PhSiO_{3/2})_{0.45}(SiO_{4/2})_{0.15}(H(Me)₂SiO_{1/2})_{0.24}. The amount of H—Si group in the silicone resin (A4) was 2.2 mmol/g. The amount of HO—Si group in the silicone resin (A4) was 3.1 mmol/g (5.3 mass %).

### Synthesis Example 4-3

<Synthesis of Silicone Resin (B4)>

Into a flask, 91.4 g of the silicone resin (1-4), 274.2 g of toluene, 91.4 g of methanol, 23.0 g of 1,3-divinyl-1,1,3,3-tetramethyldisiloxane and 7.90 mL of 70% concentrated nitric acid were put. The resulting solution was stirred at room temperature. After a lapse of 4 hours, the thus-obtained reaction solution was put into a separatory funnel and subjected to extraction with 274.2 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B4) was obtained as a colorless transparent viscous liquid.

The yield of the silicone resin (B4) was 99.2 g. The silicone resin (B4) had a mass-average molecular weight (Mw) of 1,400, a viscosity of 2,500 cP and a composition ratio of (Me₂SiO_{2/2})_{0.23}(PhSiO_{3/2})_{0.41}(SiO_{4/2})_{0.13}(CH₂═CH(Me)₂SiO_{1/2})_{0.23}. The amount of CH₂═CH—Si group in the silicone resin (B4) was 2.2 mmol/g. The amount of HO—Si group in the silicone resin (B4) was 1.9 mmol/g (3.2 mass %).

### Synthesis Example 5-1

<Synthesis of Silicone Resin (1-5)>

The same reaction process as in Synthesis Example 1-1 was performed except that: 90.2 g (0.75 mol) of Me₂Si(OMe)₂, 148.7 g (0.75 mol) of PhSi(OMe)₃ and 65.1 g (0.313 mol) of Si(OEt)₄ were used in place of 120.2 g (1.0 mol) of Me₂Si(OMe)₂ and 198.3 g (1.0 mol) of PhSi(OMe)₃. As a result, silicone resin (1-5) was obtained as a colorless transparent viscous liquid.

The yield of the silicone resin (1-5) was 137.7 g. The silicone resin (1-5) had a mass-average molecular weight (Mw) of 1,300 and a composition ratio of (Me₂SiO_{2/2})_{0.28}(PhSiO_{3/2})_{0.53}(SiO_{4/2})_{0.19}. The amount of HO—Si group in the silicone resin (1-5) was 7.4 mmol/g (13 mass %).

<Synthesis of Silicone Resin (A5)>

Into a flask, 28.6 g of the silicone resin (1-5), 85.8 g of toluene, 28.6 g of methanol, 5.69 g of 1,1,3,3-tetramethyldisiloxane and 0.14 mL of 70% concentrated nitric acid were put. The resulting solution was stirred at room temperature. After a lapse of 4 hours, the thus-obtained reaction solution was put into a separatory funnel and subjected to extraction with 85.8 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A5) was obtained as a colorless transparent viscous liquid.

The yield of the silicone resin (A5) was 27.5 g. The silicone resin (A5) had a mass-average molecular weight (Mw) of 1,600, a viscosity of 15,000 cP and a composition ratio of (Me₂SiO_{2/2})_{0.13}(PhSiO_{3/2})_{0.43}(SiO_{4/2})_{0.21}(H(Me)₂SiO_{1/2})_{0.23}. The amount of H—Si group in the silicone resin (A5) was 2.1 mmol/g. The amount of HO—Si group in the silicone resin (A5) was 2.7 mmol/g (4.6 mass %).

<Synthesis of Silicone Resin (B5)>

Into a flask, 14.3 g of the silicone resin (1-5), 42.9 g of toluene, 14.3 g of methanol, 3.95 g of 1,3-divinyl-1,1,3,3-tetramethyldisiloxane and 1.36 mL of 70% concentrated nitric acid were put. The resulting solution was stirred at room temperature. After a lapse of 4 hours, the thus-obtained reaction solution was put into a separatory funnel and subjected to extraction with 42.9 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B5) was obtained as a colorless transparent viscous liquid.

The yield of the silicone resin (B5) was 15.2 g. The silicone resin (B5) had a mass-average molecular weight (Mw) of 1,500, a viscosity of 23,000 cP and a composition ratio of (Me₂SiO_{2/2})_{0.18}(PhSiO_{3/2})_{0.40}(SiO_{4/2})_{0.19}(CH₂═CH(Me)₂SiO_{1/2})_{0.23}. The amount of CH₂═CH—Si group in the silicone resin (B5) was 2.3 mmol/g. The amount of Si—OH group in the silicone resin (B5) was 1.7 mmol/g (2.9 mass %).

### Synthesis Example 6-1

<Synthesis of Silicone Resin (1-6)>

The same reaction process as in Synthesis Example 1-1 was performed except that: 84.2 g (0.70 mol) of Me₂Si(OMe)₂, 138.8 g (0.70 mol) of PhSi(OMe)₃ and 78.1 g (0.375 mol) of Si(OEt)₄ were used in place of 120.2 g (1.0 mol) of Me₂Si(OMe)₂ and 198.3 g (1.0 mol) of PhSi(OMe)₃. As a result, silicone resin (1-6) was obtained as a colorless transparent viscous liquid.

The yield of the silicone resin (1-6) was 140.8 g. The silicone resin (1-6) had a mass-average molecular weight (Mw) of 1,500 and a composition ratio of (Me₂SiO_{2/2})_{0.29}(PhSiO_{3/2})_{0.44}(SiO_{4/2})_{0.27}. The amount of HO—Si group in the silicone resin (1-6) was 6.8 mmol/g (12 mass %).

### Synthesis Example 6-2

<Synthesis of Silicone Resin (A6)>

Into a flask, 47.9 g of the silicone resin (1-6), 143.7 g of toluene, 47.9 g of methanol, 10.9 g of 1,1,3,3-tetramethyldisiloxane and 0.26 mL of 70% concentrated nitric acid were put. The resulting solution was stirred at room temperature. After a lapse of 4 hours, the thus-obtained reaction solution was put into a separatory funnel and subjected to extraction with 143.7 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (A6) was obtained as a colorless transparent viscous liquid.

The yield of the silicone resin (A6) was 59.3 g. The silicone resin (A6) had a mass-average molecular weight (Mw) of 1,900, a viscosity of 280,000 cP and a composition ratio of (Me₂SiO_{2/2})_{0.15}(PhSiO_{3/2})_{0.40}(SiO_{4/2})_{0.22}(H(Me)₂SiO_{1/2})_{0.23}. The amount of H—Si group in the silicone resin (A6) was 1.6 mmol/g. The amount of HO—Si group in the silicone resin (A5) was 2.5 mmol/g (4.3 mass %).

### Synthesis Example 6-3

<Synthesis of Silicone Resin (B6)>

Into a flask, 23.9 g of the silicone resin (1-6), 71.7 g of toluene, 23.9 g of methanol, 7.55 g of 1,3-divinyl-1,1,3,3-tetramethyldisiloxane and 2.60 mL of 70% concentrated nitric acid were put. The resulting solution was stirred at room temperature. After a lapse of 4 hours, the thus-obtained reaction solution was put into a separatory funnel and subjected to extraction with 71.7 g of water. The organic layer was recovered. The recovered organic layer was washed by repeating the above same operation four times. Then, toluene was distilled from the organic layer by an evaporator. The organic layer was further subjected to distillation under reduced pressure by heating (130° C., 2 hours). As a result, silicone resin (B6) was obtained as a colorless transparent viscous liquid.

The yield of the silicone resin (B6) was 32.0 g. The silicone resin (B6) had a mass-average molecular weight (Mw) of 1,900, a viscosity of 280,000 cP and a composition ratio of (Me₂SiO_{2/2})_{0.19}(PhSiO_{3/2})_{0.39}(SiO_{4/2})_{0.21}(CH₂═CH(Me)₂SiO_{1/2})_{0.2}1. The amount of CH₂═CH—Si group in the silicone resin (B6) was 1.9 mmol/g. The amount of OH—Si group in the silicone resin (B5) was 1.6 mmol/g (2.7 mass %).

### Comparative Synthesis Example

<Synthesis of Silicone Resin (DA1)>

The same reaction process as in Synthesis Example 1-1 was performed except that: 92.57 g (0.77 mol) of Me₂Si(OMe)₂, 152.68 g (0.77 mol) of PhSi(OMe)₃ and 47.05 g (0.385 mol) of HSi(OMe)₃ were used in place of 120.2 g (1.0 mol) of Me₂Si(OMe)₂ and 198.3 g (1.0 mol) of PhSi(OMe)₃. As a result, silicone resin (DA1) was obtained as a colorless transparent viscous liquid.

The yield of the silicone resin (DA1) was 144.2 g. The silicone resin (DA1) had a mass-average molecular weight (Mw) of 1,400 and a composition ratio of (Me₂SiO_{2/2})_{0.34}(PhSiO_{3/2})_{0.42}(HSiO_{3/2})_{0.24}. The amount of H—Si group in the silicone resin (DA1) was 1.5 mmol/g. The amount of HO—Si group in the silicone resin (DA1) was 7.2 mmol/g (12 mass %).

<Synthesis of Silicone Resin (DA2)>

Into a 2-L three-neck flask with an agitation blade of fluororesin and a Dimroth condenser, 48.1 g (0.40 mol) of Me₂Si(OMe)₂, 79.3 g (0.40 mol) of PhSi(OMe)₃ and 13.4 g (0.10 mol) of 1,1,3,3-tetramethyldisiloxane were put. Subsequently, 106 g of 2-propanol, 79.3 g of water and 0.06 g of acetic acid were put into the flask. The inside of the flask was kept heated at 100° C. continuously for 6 hours while stirring and thereby subjected to hydrolysis and condensation. After that, the thus-obtained reaction solution was returned to room temperature. The reaction solution was put into a 1-L separatory funnel and separated into two layers with the addition of 200 mL of toluene and 200 mL of water. The aqueous layer was removed. The organic layer was washed twice with 200 mL of water and recovered. Then, toluene was distilled from the organic layer by an evaporator under reduced pressure. As a result, silicone resin (DA2) was obtained as a colorless viscous liquid.

The yield of the silicone resin (DA2) was 81.6 g. The silicone resin (DA2) had a mass-average molecular weight (Mw) of 650, a viscosity of 300 cP and a composition ratio of (Me₂SiO_{2/2})_{0.38}(PhSiO_{3/2})_{0.40}(H(Me)₂SiO_{1/2})_{0.22}. The amount of H—Si group in the silicone resin (DA2) was 1.55 mmol/g. The amount of HO—Si group in the silicone resin (DA2) was 4.7 mmol/g (8.0 mass %).

<Synthesis of Silicone Resin (DB1)>

The same reaction process as in Synthesis Example 1-1 was performed except that: 92.57 g (0.77 mol) of Me₂Si(OMe)₂, 152.68 g (0.77 mol) of PhSi(OMe)₃ and 57.07 g (0.385 mol) of CH₂═CH—Si(OMe)₃ were used in place of 120.2 g (1.0 mol) of Me₂Si(OMe)₂ and 198.3 g (1.0 mol) of PhSi(OMe)₃. As a result, silicone resin (DB1) was obtained as a colorless transparent viscous liquid.

The yield of the silicone resin (DB1) was 122.3 g. The silicone resin (DB1) had a mass-average molecular weight (Mw) of 1,200, a viscosity of 3,700 and a composition ratio of (Me₂SiO_{2/2})_{0.33}(PhSiO_{3/2})_{0.47}(CH₂═CHSiO_{3/2})_{0.20}. The amount of CH₂═CH—Si group in the silicone resin (DB1) was 1.7 mmol/g. The amount of HO—Si group in the silicone resin (DB1) was 10.7 mmol/g (18 mass %).

<Synthesis of Silicone Resin (DB2)>

Into a 2-L three-neck flask with an agitation blade of fluororesin and a Dimroth condenser, 30.1 g (0.25 mol) of Me₂Si(OMe)₂, 49.6 g (0.25 mol) of PhSi(OMe)₃ and 11.7 g (0.063 mol) of 1,3-divinyl-1,1,3,3-tetramethyldisiloxane were put. Subsequently, 59.9 g of 2-propanol, 46.3 g of water and 0.03 g of acetic acid were put into the flask. The inside of the flask was kept heated at 100° C. continuously for 6 hours while stirring and thereby subjected to hydrolysis and condensation. After that, the thus-obtained reaction solution was returned to room temperature. The reaction solution was put into a 1-L separatory funnel and separated into two layers with the addition of 100 mL of toluene and 100 mL of water. The aqueous layer was removed. The organic layer was washed twice with 100 mL of water and recovered. Then, toluene was distilled from the organic layer by an evaporator under reduced pressure. As a result, silicone resin (DB2) was obtained as a colorless viscous liquid.

The yield of the silicone resin (DB2) was 39.8 g. The silicone resin (DB2) had a mass-average molecular weight (Mw) of 1,000, a viscosity of 12,000 cP and a composition ratio of (Me₂SiO_{2/2})_{0.42} (PhSiO_{3/2})_{0.54}(CH₂═CH(Me)₂)_{0.03}. The amount of CH₂═CH—Si group in the silicone resin (DB2) was 0.05 mmol/g. The amount of HO—Si group in the silicone resin (DB2) was 8.6 mmol/g (15 mass %).

<Synthesis of Silicone Resin (DB3)>

The same reaction process as in the above synthesis of the silicone resin (DA2) was performed except that: 48.1 g (0.40 mol) of Me₂Si(OMe)₂, 79.3 g (0.40 mol) of PhSi(OMe)₃ and 23.2 g (0.20 mol) of dimethylvinylmethoxysilane were used in place of 48.1 g (0.40 mol) of Me₂Si(OMe)₂, 79.3 g (0.40 mol) of PhSi(OMe)₃ and 13.4 g (0.10 mol) of 1,1,3,3-tetramethyldisiloxane; and the resulting solution was kept heated at 100° C. continuously for 6 hours in place of being kept heated at 100° C. continuously for 15 hours. As a result, silicone resin (DB3) was obtained as a colorless viscous liquid.

The yield of the silicone resin (DB1) was 122.3 g. The silicone resin (DB1) had a mass-average molecular weight (Mw) of 1,200, a viscosity of 3,700 and a composition ratio of (Me₂SiO_{2/2})_{0.33}(PhSiO_{3/2})_{0.47}(CH₂═CHSiO_{3/2})_{0.20}. The amount of CH₂═CH—Si group in the silicone resin (DB1) was 1.7 mmol/g. The amount of HO—Si group in the silicone resin (DB1) was 10.7 mmol/g (18 mass %).

The composition ratio and physical properties (HO—Si group content amount, SiH or Si—CH═CH₂ group content amount, mass-average molecular weight, viscosity, refractive index and transparency) of the above-obtained silicone resins (A1) to (A6), silicone resins (B1) to (B6) and silicone resins (DA1) to (DA2) and (DB1) to (DB3) are indicated in TABLE 2. In TABLE 2, the abbreviation Vi refers to vinyl (CH₂═CH—).

TABLE 2

| | | Silicone resin | | | |
|---|---|---|---|---|---|
| | | (A1) | (A2) | (A3) | (A4) |
| Composition | (H—Me₂SiO_{1/2}) | 0.27 | 0.28 | 0.33 | 0.24. |
| ratio | (Me₂SiO_{2/2}) | 0.31 | 0.21 | 0.15 | 0.16 |
| | (PhSiO_{3/2}) | 0.42 | 0.45 | 0.46 | 0.45 |
| | (SiO_{4/2}) | — | 0.06 | 0.07 | 0.15 |
| | (H—SiO_{3/2}) | — | — | — | — |
| Amount of HO—Si group [mmol/g] | | 2.0 | 2.9 | 2.7 | 3.1 |
| Amount of H—Si group [mmol/g] | | 2.8 | 2.6 | 3.2 | 2.2 |
| Mass-average molecular weight [Mw] | | 1,900 | 1,000 | 1,100 | 1,500 |
| Viscosity [cP] | | 200 | 140 | 180 | 4,000 |
| Refractive index | | 1.4879 | 1.4925 | 1.4937 | 1.5007 |
| Transparency | Transmittance at 365 nm | 99% | 99% | 98% | 97% |
| | Transmittance at 405 nm | 99% | 100% | 99% | 98% |

| | | Silicone resin | | | |
|---|---|---|---|---|---|
| | | (A5) | (A6) | (DA1) | (DA2) |
| Composition | (H—Me₂SiO_{1/2}) | 0.23 | 0.23 | — | 0.22 |
| ratio | (Me₂SiO_{2/2}) | 0.13 | 0.15 | 0.34 | 0.38 |
| | (PhSiO_{3/2}) | 0.43 | 0.40 | 0.42 | 0.40 |
| | (SiO_{4/2}) | 0.21 | 0.22 | — | — |
| | (H—SiO_{3/2}) | — | — | 0.24 | — |
| Amount of HO—Si group [mmol/g] | | 2.7 | 2.5 | 7.2 | 4.7 |
| Amount of H—Si group [mmol/g] | | 2.1 | 1.6 | 1.5 | 1.6 |
| Mass-average molecular weight [Mw] | | 1,600 | 1,900 | 1,400 | 650 |
| Viscosity [cP] | | 15,000 | 280,000 | 34,000 | 300 |
| Refractive index | | 1.5018 | 1.4998 | 1.5021 | 1.4786 |
| Transparency | Transmittance at 365 nm | 99% | 98% | 98% | 99% |
| | Transmittance at 405 nm | 99% | 99% | 99% | 100% |

| | | Silicone resin | | | | |
|---|---|---|---|---|---|---|
| | | (B1) | (B2) | (B3) | (B4) | (B5) |
| Composition | (Vi-Me₂SiO_{1/2}) | 0.23 | 0.27 | 0.30 | 0.23 | 0.23 |
| ratio | (Me₂SiO_{2/2}) | 0.32 | 0.26 | 0.20 | 0.23 | 0.18 |
| | (PhSiO_{3/2}) | 0.45 | 0.42 | 0.43 | 0.41 | 0.40 |
| | (SiO_{4/2}) | — | 0.05 | 0.07 | 0.13 | 0.19 |
| | (Vi-SiO_{3/2}) | — | — | — | — | — |
| Amount of HO—Si group [mmol/g] | | 2.1 | 1.7 | 1.7 | 1.9 | 1.7 |
| Amount of Vi-Si group [mmol/g] | | 2.3 | 2.7 | 2.8 | 2.2 | 2.3 |
| Mass-average molecular weight [Mw] | | 1,800 | 1,100 | 1,300 | 1,400 | 1,500 |
| Viscosity [cP] | | 350 | 200 | 230 | 2,500 | 23,000 |
| Refractive index | | 1.4944 | 1.4944 | 1.4945 | 1.4970 | 1.5008 |
| Transparency | Transmittance at 365 nm | 98% | 99% | 98% | 98% | 99% |
| | Transmittance at 405 nm | 99% | 99% | 99% | 99% | 99% |

| | | Silicone resin | | | |
|---|---|---|---|---|---|
| | | (B6) | (DB1) | (DB2) | (DB3) |
| Composition | (Vi-Me₂SiO_{1/2}) | 0.21 | — | 0.03 | 0.16 |
| ratio | (Me₂SiO_{2/2}) | 0.19 | 0.33 | 0.42 | 0.37 |
| | (PhSiO_{3/2}) | 0.39 | 0.47 | 0.54 | 0.47 |
| | (SiO_{4/2}) | 0.21 | — | — | — |
| | (Vi-SiO_{3/2}) | — | 0.20 | — | — |
| Amount of HO—Si group [mmol/g] | | 1.6 | 10.7 | 8.6 | 6.8 |
| Amount of Vi-Si group [mmol/g] | | 1.9 | 1.7 | 0.05 | 1.30 |
| Mass-average molecular weight [Mw] | | 1,900 | 1,200 | 1,000 | 630 |
| Viscosity [cP] | | 280,000 | 3,700 | 12,000 | 300 |
| Refractive index | | 1.4989 | 1.4978 | 1.5059 | 1.4895 |
| Transparency | Transmittance at 365 nm | 98% | 99% | 99% | 95% |
| | Transmittance at 405 nm | 99% | 99% | 100% | 98% |

<Curable Silicone Resin Compositions and Cured Products Thereof>

Compositions were prepared and cured into cured products. The viscosity of the respective compositions and the physical properties (hardness, adhesion, heat resistance, transparency, heat resistant transparency, linear expansion coefficient, 5% weight reduction temperature and bonding strength) of the respective cured products, the curing start temperature of the respective compositions and the appearance of the respective cured products were evaluated according to the following methods.

In each of Examples 1 to 6 and Comparative Examples 1 to 3, the composition was prepared by mixing the silicone resin component (A) (any of the silicone resins (A1) to (A6) and (DA1) to (DA2)) and the silicone resin component (B) (any of the silicone resins (B1) to (B6) and (DB1) to (DB3)) at a mass ratio of 2:1 and further mixing a platinum catalyst as the component (C).

As the platinum catalyst, a platinum-divinyltetramethyldisiloxane complex was used such that platinum was contained in an amount of 0.03 ppm in mass units relative to the total mass of the composition.

[Viscosity of Composition]

The viscosity of the composition was measured at 25° C. with a rotating viscometer (manufactured by Brookfield Engineering Laboratories Inc., model: DV-II+PRO) in combination with a temperature control unit (manufactured by Brookfield Engineering Laboratories Inc., model: THERMOSEL).

[Hardness of Cured Product]

The cured product was formed by feeding the composition into a mold (diameter: 25 mm), heating the composition in the air at 90° C. for 1 hour and further heating the composition at 150° C. for 4 hours. The Shore A hardness or Shore D hardness of the cured product was measured with a durometer (manufactured by Tecklock Corporation, model: GS-719R, GS-720R) according to JIS K 7217 “Testing Methods for Durometer Hardness of Plastics”. In Comparative Examples 2 and 3, the hardness evaluation test was not conducted because the compositions were uncured.

[Adhesion of Cured Product]

The cured product, 16 samples for each composition, was formed by feeding the composition into a 3528SMD type PPA resin package (3528-surface-mounted polyphthalamide package) (dimensions: 3.5 mm×2.8 mm×0.4 mm), heating the composition in the air at 90° C. for 1 hour and further heating the composition at 150° C. for 4 hours. Each of the samples was observed with an optical microscope. The sample was judged as “separated” when there occurred separation of the cured product from the package. When there occurred no separation of the cured product from the package, the sample was judged as “adhered”. The number of samples judged as “adhered”, out of 16 samples, was determined as the “number of passing grade samples”. In Comparative Examples 2 and 3, the adhesion evaluation test was not also conducted because the compositions were uncured.

[Transparency of Cured Product]

The cured product was formed with a diameter of 22 mm and a thickness of 2 mm by feeding the composition into a mold (diameter: 22 mm), heating the composition in the air at 90° C. for 1 hour and further heating the composition at 150° C. for 4 hours. The transmittance of the cured product at 405 nm and 365 nm wavelengths was measured with an ultraviolet-visible spectrophotometer (manufactured by Shimadzu Corporation, model: UV-3150). In Comparative Examples 2 and 3, the transparency evaluation test was not also conducted because the compositions were uncured.

[Heat Resistant Transparency of Cured Product]

The cured product was formed with a diameter of 22 mm and a thickness of 2 mm by feeding the composition into a mold (diameter: 22 mm), heating the composition in the air at 90° C. for 1 hour and further heating the composition at 150° C. for 4 hours. The cured product was then subjected to heating at 200° C. for 100 hours. After that, the transmittance of the cured product at 405 nm and 365 nm wavelengths was measured with an ultraviolet-visible spectrophotometer (manufactured by Shimadzu Corporation, model: UV-3150). In Comparative Examples 2 and 3, the heat resistant transparency evaluation test was not also conducted because the compositions were uncured.

[Linear Expansion Coefficient of Cured Product]

The cured product was formed by feeding 0.7 g of the composition into a fluororesin tube (inner diameter: 5.8 mm, length: 1.8 mm), heating the composition in the air at 90° C. for 1 hour and further heating the composition at 150° C. for 4 hours. The linear expansion coefficient of the cured product was measured with Thermo Plus TMA8310 (manufactured by Rigaku Corporation) while heating the cured product from 25° C. to 200° C. at a temperature rise speed of 5° C./min in the air. This measurement was conducted twice; and the second measurement result was adopted. In Comparative Examples 2 and 3, the linear expansion coefficient evaluation test was not also conducted because the compositions were uncured.

[5% Weight Reduction Temperature (T_{d5})]

The cured product was formed by heating the composition in the air at 90° C. for 1 hour and further heating the composition at 150° C. for 4 hours. While heating the cured product from 25° C. to 500° C. at a temperature rise speed of 5° C./min in the air, the temperature (T_{d5}) at which the weight of the cured product became smaller by 5% than the original weight was measured with Thermo Plus TG8120 (manufactured by Rigaku Corporation) as a thermogravimetric/differential thermal analyzer (abbreviation: TG-DTA). In Comparative Examples 2 and 3, the 5% weight reduction temperature evaluation test was not also conducted because the compositions were uncured.

[Bonding Strength of Cured Product]

The cured product was formed as a test sample by mixing the composition with zirconia balls of 50 μm diameter, applying the composition between a glass chip (dimensions: 5.0 mm×5.0 mm×1.1 mm) and an aluminum substrate (dimensions: 50 mm×50 mm×2.0 mm), heating the composition in the air at 90° C. for 1 hour and further heating the composition at 150° C. for 4 hours. The bonding power (bonding strength) of the test sample was measured a bond tester (manufactured by Daisy Japan Co., Ltd., model: Dage 400 Plus). The term “cohesive failure” was assigned when the bonding strength was not measured due to the occurrence of breakage in the cured product during the measurement. In Comparative Examples 2 and 3, the bonding strength evaluation test was not also conducted because the compositions were uncured.

[Curing Start Temperature]

The composition was left still for 10 minutes after the preparation. While heating the composition from 25° C. to 150° C. at a shear speed of 30 [l/s] and at a constant temperature rise speed of 2.09° C./min, the change over time of the viscosity of the composition was measured with a rotating viscometer (manufactured by Brookfield Engineering Laboratories Inc., model: DV-II+PRO) in combination with a temperature control unit (manufactured by Brookfield Engineering Laboratories Inc., model: THERMOSEL). The temperature at which the viscosity exceeded 30,000 cP was determined as the curing start temperature.

[Curing Appearance]

The cured product, 3 samples for each composition, was formed by spreading 1 g of the composition as a thin film on a glass mold (diameter: 22 mm), heating the composition in the air at 90° C. for 1 hour, further heating the composition at 150° C. for 4 hours and naturally cooling the cured product to 25° C. The appearance of each of the samples was visually inspected. The appearance of the cured product was evaluated as “good” when all of the samples were transparent with the occurrence of no air bubbles and no cracks. The appearance of the cured product was evaluated as “bubbling” when the air bubbles were observed in any of the samples. The term “uncured” was assigned when the composition was not cured and remained in viscous liquid form.

The evaluation test results of the compositions and cured products of Examples 1 to 6 and Comparative Examples 1 to 3 are indicated in TABLE 3.

TABLE 3

| | | | | | | | | Comp. | Comp. | Comp. |
|---|---|---|---|---|---|---|---|---|---|---|
| | | Ex. 1 | Ex. 2 | Ex. 3 | Ex. 4 | Ex. 5 | Ex. 6 | Ex. 1 | Ex. 2 | Ex. 3 |
| Composition | Component (A) | (A1) | (A2) | (A3) | (A4) | (A5) | (A6) | (DA1) | (DA2) | (DA2) |
| | Component (B) | (B1) | (B2) | (B3) | (B4) | (B5) | (B6) | (DB1) | (DB2) | (DB3) |
| | Amount of platinum atom | 0.3 ppm | | | | | | | | |
| | Viscosity | 200 | 100 | 200 | 2,800 | 23,000 | 120,000 | 12,000 | 400 | 300 |
| | Amount of Si—OH group | 2.0 | 2.5 | 2.4 | 2.7 | 2.4 | 2.2 | 8.4 | 6.0 | 5.4 |
| | [mmol/g] | | | | | | | | | |
| Shore hardness | Shore A | A40 | A8 | A42 | A78 | A92 | A92 | A94 | — | — |
| | Shore D | — | — | — | D18 | D58 | D69 | D60 | — | — |
| Adhesion test | | 16/16 | 8/16 | 16/16 | 16/16 | 16/16 | 3/16 | 0/16 | — | — |
| (Number of passing grade samples/16 samples) | | | | | | | | | | |
| Transparency of | Transmittance at 365 nm | 89% | 88% | 89% | 89% | 89% | 89% | 43% | — | — |
| cured product | Transmittance at 405 nm | 90% | 90% | 90% | 90% | 90% | 90% | 45% | — | — |
| Heat resistant | Transmittance at 365 nm | 81% | 80% | 80% | 80% | 79% | 80% | — | — | — |
| transparency of | Transmittance at 405 nm | 88% | 89% | 88% | 88% | 88% | 88% | — | — | — |
| cured product | | | | | | | | | | |
| Linear expansion coefficient [ppm] | | 248 | 295 | 242 | 214 | 195 | 153 | 162 | — | — |
| Heat resistance: T_{d5} [° C.] | | 335 | 285 | 395 | 408 | 397 | 405 | 439 | — | — |
| Bonding strength | Glass | cohesive | cohesive | cohesive | 187 | 261 | 269 | 25 | — | — |
| [N] | | failure | failure | failure | | | | | | |
| | Alumina | cohesive | cohesive | cohesive | 117 | 244 | 202 | 43 | — | — |
| | | failure | failure | failure | | | | | | |

| | | | | | | | | | |
|---|---|---|---|---|---|---|---|---|---|
| Curing start temperature [° C.] | 79 | 60 | 58 | 74 | 67 | 64 | >150 | >150 | >150 |
| Appearance of cured product | good | good | good | good | good | good | bubbling | uncured | uncured |

The cured products of Examples 4 to 6, in which the composition ratio of (SiO)_{4/2} in the silicone resin component (A) or (B) was 0.1 or more, had a Shore A hardness exceeding 70 and a Shore D hardness exceeding 10.

The cured products of Examples 4 to 6, in which the composition ratio of (SiO)_{4/2} in the silicone resin component (A) or (B) was 0.1 or more, had a bonding strength exceeding 100 N. In Examples 1 to 3, the bonding strength measurement values was not obtained due to the occurrence of breakage (cohesive failure) in the resin. On the other hand, the cured product of Comparative Example 1 had a bonding strength lower than 50 N.

As to the adhesion of the cured product, there was no sample in which the package was favorably sealed with the cured product in Comparative Example 1 due to the occurrence of air bubbles in the cured product. On the other hand, the samples in which the cured product was adhered to the package were found in Examples 1 to 6. In each of Examples 1 to 6, the adhesion of the cured product was observed in a half or more of the samples. In particular, the adhesion of the cured product was observed in all of the sixteen samples in Examples 1 and 3 to 5.

As to the transparency of the cured product, the cured products of Examples 1 to 6 had a high transmittance of 88% or higher at 365 nm wavelength and 79% or higher at 405 nm wavelength. On the other hand, the cured product of Comparative Example 1 had a transmittance of 45% or lower. The reason for such low transmittance is assumed to be the occurrence of air bubbles in the cured product.

As to the transparency of the cured product after continuous heating at 200° C. for 100 hours (i.e. heat resistance transparency), the cured products of Examples 1 to 6 had a high transmittance of 88% or higher at 405 nm wavelength and 79% or higher at 365 nm wavelength.

As to the heat resistance of the cured product, the cured products of Examples 1 to 6 had a high T_{d5} value of 285° C. or higher. Among others, the cured products of Examples 3 to 6 had a particularly high T_{d5} value of 395° C. or higher.

The cured products of Examples 1 to 6 had a linear expansion coefficient of 300 vol ppm or lower. In particular, the cured products of Examples 1 and 3 to 6 had a linear expansion coefficient of 250 vol ppm or lower. Among others, the cured products of Examples 4 to 6 had a favorable linear expansion coefficient of 215 vol ppm or lower. The lower the linear expansion coefficient of the cured product, the smaller the amount of volume expansion and contraction of the cured product during heat cycles, the less likely the separation of the cured product from the mold. For this reason, it is preferable that the linear expansion coefficient of the cured product is low.

The compositions of Examples 1 to 6 had a low curing start temperature of 58 to 79° C. and showed good curability. On the other hand, the compositions of Comparative Examples 1 to 3 did not start curing even when heated to 150° C.

It has been shown by the above results that the compositions of Examples 1 to 6, each of which fell within the scope of the present invention, had good curability and heat resistant transparency. It has also been shown that the compositions of Examples 1 to 6 had good adhesion. Among others, the cured products of Examples 3 to 6 had good heat resistance and Shore hardness. The cured products of Examples 4 to 6 had good bonding strength.

<Evaluation of Heat Resistance Transparency against Platinum Amount>

Compositions 1-1 to 1-5 were each prepared by mixing the silicone resin (A1) as the component (A) and the silicone resin (B1) as the component (B) at a mass ratio of 2:1 and further mixing a platinum catalyst as the component (C). Further, comparative composition 1-1 was prepared by mixing the silicone resin (A1) and the silicone resin (B1) as the component (B) without mixing a platinum catalyst as the component (C).

As the platinum catalyst, a platinum-divinyltetramethyldisiloxane complex was used such that the platinum was contained in a predetermined amount relative to the total mass of the composition.

Compositions 4-1 to 4-3 and comparative example 4-1 were prepared in the same manner as above except that the silicone resins (A4) and (B4) were used in place of the silicone resins (A1) and (B1), respectively.

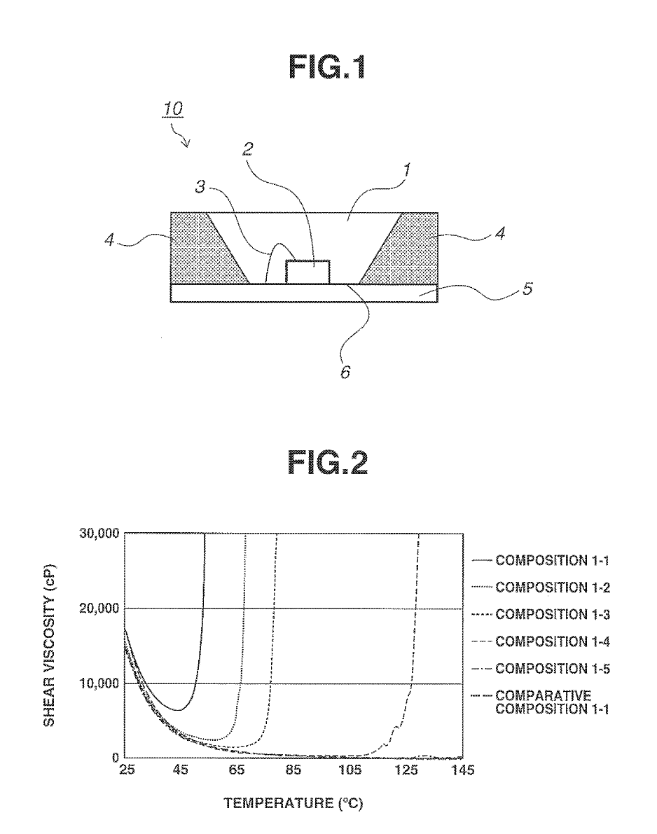

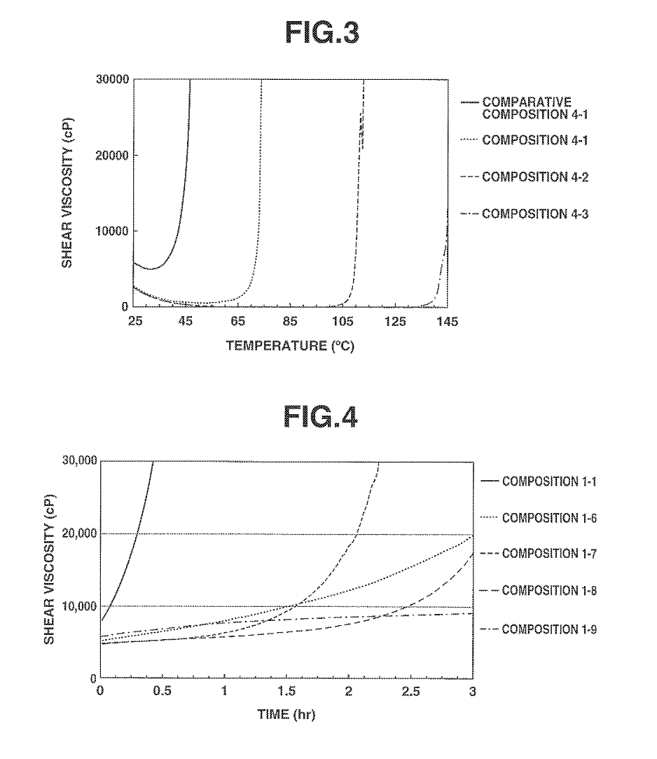

The respective compositions and comparative compositions were each tested for the physical properties (transparency and heat resistant transparency) of the cured product, the curing start temperature of the composition and the appearance of the cured product according to the methods explained in the above sections [Transparency of Cured Product], [Heat Resistant Transparency of Cured Product], [Curing Start Temperature] and [Curing Appearance]. The evaluation test results are indicated in TABLE 4 and FIGS. 2 and 3.

TABLE 4

| | | | | | | | Comparative |
|---|---|---|---|---|---|---|---|
| | | Composition | Composition | Composition | Composition | Composition | composition |
| | | 1-1 | 1-2 | 1-3 | 1-4 | 1-5 | 1-1 |
| Composition | Component (A) | Silicone resin (A1) | | | | | |
| | Component (B) | Silicone resin (B1) | | | | | |
| | Amount of platinum atom | 2.0 | 0.7 | 0.3 | 0.03 | 0.003 | 0 |
| | [ppm] | | | | | | |
| Transparency of | Transmittance at 365 nm | 88% | 88% | 88% | 89% | 89% | — |
| cured product | Transmittance at 405 nm | 90% | 89% | 90% | 90% | 90% | — |
| Heat resistant | Transmittance at 365 nm | 75% | 80% | 83% | 88% | 87% | — |
| transparency of | Transmittance at 405 nm | 86% | 88% | 89% | 90% | 89% | — |
| cured product | | | | | | | |

| | | | | | | |
|---|---|---|---|---|---|---|
| Curing start temperature [° C.] | 52 | 68 | 79 | 130 | >150 | >150 |
| Appearance of cured product | good | good | good | good | good | uncured |

| | | | |
|---|---|---|---|
| Comparative | | | |
| composition | Composition | Composition | Composition |
| 4-1 | 4-1 | 4-2 | 4-3 |

| | | |
|---|---|---|
| Composition | Component (A) | Silicone resin (A4) |
| | Component (B) | Silicone resin (B4) |

| | | | | | |
|---|---|---|---|---|---|
| | Amount of platinum atom | 3.3 | 0.3 | 0.03 | 0.003 |
| | [ppm] | | | | |
| Transparency of | Transmittance at 365 nm | 88% | 89% | 89% | 91% |
| cured product | Transmittance at 405 nm | 90% | 90% | 90% | 91% |
| Heat resistant | Transmittance at 365 nm | 70% | 80% | 81% | 84% |
| transparency of | Transmittance at 405 nm | 85% | 88% | 88% | 89% |
| cured product | | | | | |

| | | | | |
|---|---|---|---|---|
| Curing start temperature [° C.] | 45 | 73 | 111 | 147 |
| Appearance of cured product | good | good | good | good |

As indicated in TABLE 4, the cured products of the compositions 1-1 to 1-5 and 4-1 to 4-3 and the comparative composition 4-1 had good appearance without the occurrence of air bubbles and cracks. Even each of the compositions 1-5 and 4-3, in which the amount of platinum relative to the total mass of the composition was 0.003 mass ppm, had good appearance. It is thus apparent that the components (A) and (B) of these respective compositions had good curability. On the other hand, the comparative composition 1-1 with no platinum catalyst was uncured. A cured product of the comparative composition 1-1 was not obtained and was not tested for the physical properties.

Further, the curing start temperature of the cured product became higher as the amount of platinum increased. Although the curing start temperature of the composition 1-5 was higher than 150° C., the composition 1-5 was cured under the above curing conditions (heating at 90° C. for 1 hour and further heating at 150° C. for 4 hours) without problem.

All of the cured products had a transmittance of 88 to 91% at 405 nm wavelength and 89 to 91% at 365 nm wavelength and showed good transparency.

As to the transparency of the cured product after continuous heating at 200° C. for 100 hours (i.e. heat resistance transparency), all of the cured products of Examples 1 to 6 had a high transmittance of 85% or higher at 405 nm wavelength. However, the cured product of the comparative composition 4-1 had a transmittance of 70% after the continuous heating and showed deterioration in transparence; whereas the cured products of the compositions 1-1 to 1-5 and 4-1 to 4-3 maintained a transmittance of 75% or higher at 365 nm wavelength even after the continuous heating.

It has been shown by the above results that the compositions 1-1 to 1-5 and 4-1 to 4-4, each of which fell within the scope of the present invention, had good curability and heat resistant transparency.

<Evaluation of Heat Resistance Transparency with Curing Retardant>

Compositions 1-6 to 1-9 were each prepared by mixing the silicone resin (A1) as the component (A) and the silicone resin (B1) as the component (B) at a mass ratio of 2:1, mixing a platinum catalyst as the component (C) and further mixing a curing retardant.

As the platinum catalyst, a platinum-divinyltetramethyldisiloxane complex was used such that the platinum was contained in an amount of 2.0 ppm in mass units relative to the total mass of the components (A) to (C).

The curing retardant was added in an amount of 70 to 80 equivalents assuming 2.0 mass ppm of platinum as 1 equivalent. For the preparation of the composition 1-6, 118 μg of dimethyl maleate was used as the curing retardant per 1 g of the composition. For the preparation of the composition 1-7, 67 μg of 2-methyl-3-butyn-2-ol was used as the curing retardant per 1 g of the composition. For the preparation of the composition 1-8, 94 μg of 1-ethynyl-1-cyclohexanol was used as the curing retardant per 1 g of the composition. For the preparation of the composition 1-9, 86 μg of tetramethylethylenediamine was used as the curing retardant per 1 g of the composition.

The compositions 1-6 to 1-9 as well as the composition 1-1 as an example of the composition with no curing retardant were each tested for the physical properties (transparency and heat resistant transparency) and appearance of the cured product and the curing start time of the composition according to the methods explained in the above sections [Transparency of Cured Product], [Heat Resistant Transparency of Cured Product] and [Curing Appearance] and explained in the following section [Curing Start Time]. The evaluation results are indicated in TABLE 5 and FIG. 4.

[Curing Start Time]

The composition was left still for 10 minutes after the preparation. The viscosity of the composition was measured, with a rotating viscometer (manufactured by Brookfield Engineering Laboratories Inc., model: DV-II+PRO) in combination with a temperature control unit (manufactured by Brookfield Engineering Laboratories Inc., model: THERMOSEL), every minute for 3 hours at 25° C. and a shear speed of 30 [l/s]. The time lapsed from the start of the viscosity measurement until when the viscosity exceeded 30,000 cP was determined as the curing start time.

TABLE 5

| | | Composition | Composition | Composition | Composition | Composition |
|---|---|---|---|---|---|---|
| | | 1-1 | 1-6 | 1-7 | 1-8 | 1-9 |
| Amount of platinum atom | | 2.0 ppm | | | | |
| Curing retardant | Kind | — | DMM | MBY | ECH | TMEDA |
| | Amount [μg/g] | — | 118 | 67 | 94 | 86 |
| | (equivalents) | | (80) | (78) | (74) | (72) |
| Curing start time [min] | | 26 | >180 | 134 | >180 | >180 |
| Transparency of | Transmittance at 365 nm | 89% | 89% | 89% | 89% | 87% |
| cured product | Transmittance at 405 nm | 90% | 90% | 90% | 90% | 89% |
| Heat resistant | Transmittance at 365 nm | 76% | 75% | 74% | 75% | 75% |
| transparency of | Transmittance at 405 nm | 87% | 86% | 86% | 86% | 85% |
| cured product | | | | | | |

| | | | | | |
|---|---|---|---|---|---|
| Appearance of cured product | good | good | good | good | good |

DMM: dimethyl maleate
MBY: 2-methyl-3-butyn-2-ol
ECH: 1-ethynyl-1-cyclohexanol
TMBDA: tetramethylethylenediamine

As indicated in TABLE 5, the cured products of the compositions 1-1 and 1-6 to 1-9 had good appearance without the occurrence of air bubbles and cracks. The curing start time of the composition 1-1 was 26 minutes. On the other hand, the curing start time of the compositions 1-6 to 1-9, in each of which the curing retardant was added, was over 2 hours. The curability of the composition was thus controlled with the addition of the curing retardant.

Further, the cured products of the compositions 1-6 to 1-9 had a transmittance of 89% or higher at 405 nm wavelength and 87% or higher at 365 nm wavelength. The transparency of the cured product was not deteriorated with the addition of the curing retardant.

As to the transparency after continuous heating at 200° C. for 100 hours (i.e. heat resistance transparency), the cured products of the compositions 1-6 to 1-9 had a transmittance of 85% or higher at 405 nm wavelength and 74% or higher at 365 nm wavelength. Each of the cured products of the compositions 1-6 to 1-9 showed heat resistant transparency nearly equal to that of the composition 1-1 with no curing retardant.

<Evaluation of Heat Resistance Transparency with Light Stabilizer and Antioxidant>

Compositions 4-4 to 4-6 were each prepared by mixing the silicone resin (A4) as the component (A) and the silicone resin (B4) as the component (B) at a mass ratio of 2:1, mixing a platinum catalyst as the component (C) and further mixing a light stabilizer or antioxidant.

As the platinum catalyst, a platinum-divinyltetramethyldisiloxane complex was used such that the platinum was contained in an amount of 0.2 ppm in mass units relative to the total mass of the components (A) to (C).

The light stabilizer or antioxidant was added in an amount of 0.05 to 0.2 mass % relative to the total mass of the components (A) to (C). For the preparation of the composition 4-4, 0.5 mg of bis(2,2,6,6-tetramethyl-4-piperidyl)sebacate was used as the light stabilizer per 1 g of the composition. For the preparation of the composition 4-5, 1.0 mg of bis(2,2,6,6-tetramethyl-4-piperidyl)sebacate was used as the light stabilizer per 1 g of the composition. For the preparation of the composition 4-6, 1.5 mg of 1,3,5-tris(3,5-di-tert-butyl-4-hydroxybenzyl)-1,3,5-triazine-2,4,6-(1H,3H,5H)-trion and 0.5 mg of 2,2-bis({[3-(dodecylthio)propionyl]oxy}methyl)-1,3-propanediyl=bis[3-(dodecylthio)propionate] were used as the antioxidant per 1 g of the composition.

The compositions 4-4 to 4-6 as well as the composition 4-1 as an example of the composition with no light stabilizer and no antioxidant were each tested for the physical properties (transparency and heat resistant transparency) and appearance of the cured product according to the method explained in the above section [Curing Appearance] and explained in the following section [Heat Resistant Transparency of Cured Product with Antioxidant].

[Heat Resistant Transparency of Cured Product with Antioxidant]

The cured product was formed with a diameter of 22 mm and a thickness of 2 mm by heating the composition in the air at 90° C. for 1 hour and further heating the composition at 150° C. for 4 hours. The transmittance of the cured product at 405 nm and 365 nm wavelengths was measured with an ultraviolet-visible spectrophotometer (manufactured by Shimadzu Corporation, model: UV-3150). Then the cured product was additionally heated at 200° C. After a lapse of 100 hours and after a lapse of 200 hours, the cured product was once cooled to room temperature. After the cooling, the transmittance of the cured product was measured in the same manner as above. The change rate of the transmittance of the cured product after the heating to the transmittance of the cured product before the heating was calculated based on the measurements results.

The evaluation test results of the compositions 4-1 and 4-4 to 4-6 are indicated in TABLE 6.

TABLE 6

| | | | Composition | | | |
|---|---|---|---|---|---|---|
| | | | 4-1 | 4-2 | 4-3 | 4-4 |
| Composition | Component (A) | | Silicone resin (A4) | | | |
| | Component (B) | | Silicone resin (B4) | | | |
| | Amount of platinum atom [ppm] | | 0.2 | | | |
| | Light stabilizer | Kind | — | BTPS | BTPS | — |
| | | Amount | — | 0.05 | 1.0 | — |
| | | [mass %] | | | | |
| | Antioxidant | Kind | — | — | — | AOₓ₋₁, AOₓ₋₂ |
| | | Amount | — | — | — | AOₓ₋₁: 0.15 |
| | | [mass %] | | | | AOₓ₋₂: 0.05 |
| Transparency of | Change of | after 0 hour | 1 | 1 | 1 | 1 |
| cured product | transmittance | after 100 hours | 0.97 | 0.98 | 0.97 | 0.99 |
| | at 405 nm | after 200 hours | 0.96 | 0.97 | 0.95 | 0.98 |
| Heat resistant | Change of | after 0 hour | 1 | 1 | 1 | 1 |
| transparency of | transmittance | after 100 hours | 0.92 | 0.95 | 0.93 | 0.97 |
| cured product | at 365 nm | after 200 hours | 0.87 | 0.92 | 0.88 | 0.92 |

| | | | | |
|---|---|---|---|---|
| Appearance of cured product | good | good | good | good |

BTPS: bis(2,2,6,6-tetramethyl-4-piperidyl)sebacate
AOₓ₋₁: 1,3,5-tris(3,5-di-tert-buryl-4-hydroxybenzyl)-1,3,5-triazine-2,4,6-(1H,3H,5H)-trion
AOₓ₋₂: 2,2-bis({[3-(dodecylthio)propionyl]oxy}methyl)-1,3-propanediyl = bis[3-(dodecylthio)propionate]

As indicated in TABLE 6, the cured products of the compositions 4-1 and 4-4 to 4-6 had good appearance without the occurrence of air bubbles and cracks. After 100 hours and 200 hours of additional heating at 200° C., all of the cured products of the compositions showed a transmittance lightly lower than that after 0 hour (i.e. the transmittance of the cured product at 405 nm and 365 nm wavelengths before the further curing). However, the cured products of the compositions 4-4 to 4-6 each containing the light stabilizer or antioxidant had a smaller transmittance change rate than that of the composition 4-1. The cured product of the composition 4-6 containing the antioxidant had a particularly small transmittance change rate. As is apparent from these results, the addition of the light stabilizer or antioxidant led to improvement in the heat resistant transparency of the cured product.

### Synthesis Example 7-1

<Molecular Weight Increase of Silicone Resin (I-1)>

Into a 2-L four-neck flask with an agitation blade of fluororesin, a Dean-Stark trap and a Dimroth condenser, 1000 g of silicone resin pursuant to the silicone resin (I-1) obtained in Synthesis Example 1-1 was put. Subsequently, 250 g of toluene was put into the flask. The inside of the flask was kept heated at 130° C. continuously for 24 hours while stirring and thereby subjected to hydrolysis and condensation. After that, the thus-obtained reaction solution was returned to room temperature. As a result, silicone resin (II) with toluene was obtained.

The silicone resin (II) had a mass-average molecular weight (Mw) of 5,200 and a composition ratio of (Me₂SiO_{2/2})_{0.50}(PhSiO_{3/2})_{0.50}. The amount of HO—Si group in the silicone resin (II) was 4.5 mmol/g (6.7 mass %). The amount of toluene in the silicone resin (II) was 20.49 mass %.

### Synthesis Example 7-2

<Synthesis of Silicone Resin (A7)>

Into a flask, 130.00 g of the silicone resin (II), 288.91 g of toluene, 103.36 g of methanol, 10.25 g of 1,1,3,3-tetramethyldisiloxane and 0.24 mL of 70% concentrated nitric acid were put. The resulting solution was stirred at room temperature. After a lapse of 4 hours, the thus-obtained reaction solution was put into a separatory funnel and subjected to extraction with 310 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A7) was obtained as a colorless transparent viscous liquid.

The yield of the silicone resin (A7) was 103.23 g. The silicone resin (A7) had a mass-average molecular weight (Mw) of 6,100, a viscosity of 5,100 cP and a composition ratio of (Me₂SiO_{2/2})_{0.39}(PhSiO_{3/2})_{0.47}(H(Me)₂SiO_{1/2})_{0.14}. The amount of H—Si group in the silicone resin (A7) was 1.26 mmol/g. The amount of HO—Si group in the silicone resin (A7) was 2.66 mmol/g (4.5 mass %).

### Synthesis Example 7-3

<Synthesis of Silicone Resin (B7)>

Into a flask, 65.00 g of the silicone resin (II), 144.45 g of toluene, 51.68 g of methanol, 6.50 g of 1,3-divinyl-1,1,3,3-tetramethyldisiloxane and 2.24 mL of 70% concentrated nitric acid were put. The resulting solution was stirred at room temperature. After a lapse of 4 hours, the thus-obtained reaction solution was put into a separatory funnel and subjected to extraction with 155 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B7) was obtained as a colorless transparent viscous liquid.

The yield of the silicone resin (B7) was 49.34 g. The silicone resin (B7) had a mass-average molecular weight (Mw) of 4,800, a viscosity of 6,500 cP and a composition ratio of (Me₂SiO_{2/2})_{0.42}(PhSiO_{3/2})_{0.49}(CH₂CH₂═CH(Me)₂SiO_{1/2})_{0.09}. The amount of CH₂═CH—Si group in the silicone resin (B7) was 0.87 mmol/g. The amount of HO—Si group in the silicone resin (B7) was 2.6 mmol/g (4.3 mass %).

### Synthesis Example 8-1

<Synthesis of Silicone Resin (A8)>

Into a flask, 130.00 g of the silicone resin (II), 288.91 g of toluene, 103.36 g of methanol, 29.49 g of 1,1,3,3-tetramethyldisiloxane and 0.30 mL of 70% concentrated nitric acid were put. The resulting solution was stirred at room temperature. After a lapse of 4 hours, the thus-obtained reaction solution was put into a separatory funnel and subjected to extraction with 310 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A8) was obtained as a colorless transparent viscous liquid.

The yield of the silicone resin (A8) was 107.48 g. The silicone resin (A8) had a mass-average molecular weight (Mw) of 5,600, a viscosity of 2,800 cP and a composition ratio of (Me₂SiO_{2/2})_{0.40}(PhSiO_{3/2})_{0.48}(H(Me)₂SiO_{1/2})_{0.12}. The amount of H—Si group in the silicone resin (A8) was 1.40 mmol/g. The amount of HO—Si group in the silicone resin (A8) was 2.1 mmol/g (3.6 mass %).

### Synthesis Example 8-2

<Synthesis of Silicone Resin (B8)>

Into a flask, 65.00 g of the silicone resin (II), 144.45 g of toluene, 51.68 g of methanol, 8.67 g of 1,3-divinyl-1,1,3,3-tetramethyldisiloxane and 2.98 mL of 70% concentrated nitric acid were put. The resulting solution was stirred at room temperature. After a lapse of 4 hours, the thus-obtained reaction solution was put into a separatory funnel and subjected to extraction with 155 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B8) was obtained as a colorless transparent viscous liquid.

The yield of the silicone resin (B8) was 51.78 g. The silicone resin (B8) had a mass-average molecular weight (Mw) of 5,300, a viscosity of 5,000 cP and a composition ratio of (Me₂SiO_{2/2})_{0.39}(PhSiO_{3/2})_{0.44}(CH₂═C H(Me)₂SiO_{1/2})_{0.17}. The amount of CH₂═CH—Si group in the silicone resin (B8) was 1.05 mmol/g. The amount of HO—Si group in the silicone resin (B8) was 2.3 mmol/g (4.0 mass %).

### Synthesis Example 9-1

<Synthesis of Silicone Resin (A9)>

Into a flask, 130.00 g of the silicone resin (II), 288.91 g of toluene, 103.36 g of methanol, 15.62 g of 1,1,3,3-tetramethyldisiloxane and 0.37 mL of 70% concentrated nitric acid were put. The resulting solution was stirred at room temperature. After a lapse of 4 hours, the thus-obtained reaction solution was put into a separatory funnel and subjected to extraction with 310 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A9) was obtained as a colorless transparent viscous liquid.

The yield of the silicone resin (A9) was 106.52 g. The silicone resin (A9) had a mass-average molecular weight (Mw) of 5,800, a viscosity of 2,100 cP and a composition ratio of (Me₂SiO_{2/2})_{0.38}(PhSiO_{3/2})_{0.42}(H(Me)₂SiO_{1/2})_{0.20}. The amount of H—Si group in the silicone resin (A9) was 1.81 mmol/g. The amount of HO—Si group in the silicone resin (A9) was 1.7 mmol/g (2.9 mass %).

### Synthesis Example 9-2

<Synthesis of Silicone Resin (B9)>

Into a flask, 65.00 g of the silicone resin (II), 144.45 g of toluene, 51.68 g of methanol, 10.84 g of 1,3-divinyl-1,1,3,3-tetramethyldisiloxane and 3.73 mL of 70% concentrated nitric acid were put. The resulting solution was stirred at room temperature. After a lapse of 4 hours, the thus-obtained reaction solution was put into a separatory funnel and subjected to extraction with 155 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B9) was obtained as a colorless transparent viscous liquid.

The yield of the silicone resin (B9) was 49.16 g. The silicone resin (B9) had a mass-average molecular weight (Mw) of 5,200, a viscosity of 3,900 cP and a composition ratio of (Me₂SiO_{2/2})_{0.39}(PhSiO_{3/2})_{0.48}(CH₂═C H(Me)₂SiO_{1/2})_{0.13}. The amount of CH₂═CH—Si group in the silicone resin (B9) was 1.17 mmol/g. The amount of HO—Si group in the silicone resin (B9) was 2.2 mmol/g (3.7 mass %).

### Synthesis Example 10-1

<Synthesis of Silicone Resin (A10)>

Into a flask, 120.00 g of the silicone resin (II), 306.93 g of toluene, 106.34 g of methanol, 24.59 g of 1,1,3,3-tetramethyldisiloxane and 0.59 mL of 70% concentrated nitric acid were put. The resulting solution was stirred at room temperature. After a lapse of 4 hours, the thus-obtained reaction solution was put into a separatory funnel and subjected to extraction with 320 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A10) was obtained as a colorless transparent viscous liquid.

The yield of the silicone resin (A10) was 110.66 g. The silicone resin (A10) had a mass-average molecular weight (Mw) of 5,700, a viscosity of 1,600 cP and a composition ratio of (Me₂SiO_{2/2})_{0.35}(PhSiO_{3/2})_{0.41}(H(Me)₂SiO_{1/2})_{0.24}. The amount of H—Si group in the silicone resin (A10) was 2.25 mmol/g. The amount of HO—Si group in the silicone resin (A10) was 1.18 mmol/g (2.0 mass %).

### Synthesis Example 10-2

<Synthesis of Silicone Resin (B10)>

Into a flask, 60.00 g of the silicone resin (II), 153.47 g of toluene, 53.17 g of methanol, 17.07 g of 1,3-divinyl-1,1,3,3-tetramethyldisiloxane and 5.87 mL of 70% concentrated nitric acid were put. The resulting solution was stirred at room temperature. After a lapse of 4 hours, the thus-obtained reaction solution was put into a separatory funnel and subjected to extraction with 160 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B10) was obtained as a colorless transparent viscous liquid.

The yield of the silicone resin (B10) was 55.70 g. The silicone resin (B10) had a mass-average molecular weight (Mw) of 4,800, a viscosity of 3,000 cP and a composition ratio of (Me₂SiO_{2/2})_{0.40}(PhSiO_{3/2})_{0.45}(CH₂═CH(Me)₂SiO_{1/2})_{0.15}. The amount of CH₂═CH—Si group in the silicone resin (B10) was 1.43 mmol/g. The amount of HO—Si group in the silicone resin (B10) was 1.9 mmol/g (3.0 mass %).

### Synthesis Example 11-1

<Synthesis of Silicone Resin (A11)>

Into a flask, 130.00 g of the silicone resin (II), 288.91 g of toluene, 103.36 g of methanol, 31.23 g of 1,1,3,3-tetramethyldisiloxane and 0.75 mL of 70% concentrated nitric acid were put. The resulting solution was stirred at room temperature. After a lapse of 4 hours, the thus-obtained reaction solution was put into a separatory funnel and subjected to extraction with 310 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A11) was obtained as a colorless transparent viscous liquid.

The yield of the silicone resin (A11) was 113.15 g. The silicone resin (A11) had a mass-average molecular weight (Mw) of 5,700, a viscosity of 1,000 cP and a composition ratio of (Me₂SiO_{2/2})_{0.36}(PhSiO_{3/2})_{0.38}(H(Me)₂SiO_{1/2})_{0.26}. The amount of H—Si group in the silicone resin (A11) was 2.7 mmol/g. The amount of HO—Si group in the silicone resin (A11) was 0.86 mmol/g (1.5 mass %).

### Synthesis Example 11-2

<Synthesis of Silicone Resin (B11)>

Into a flask, 65.00 g of the silicone resin (II), 144.45 g of toluene, 51.68 g of methanol, 21.68 g of 1,3-divinyl-1,1,3,3-tetramethyldisiloxane and 7.45 mL of 70% concentrated nitric acid were put. The resulting solution was stirred at room temperature. After a lapse of 4 hours, the thus-obtained reaction solution was put into a separatory funnel and subjected to extraction with 155 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B11) was obtained as a colorless transparent viscous liquid.

The yield of the silicone resin (B11) was 53.64 g. The silicone resin (B11) had a mass-average molecular weight (Mw) of 5,200, a viscosity of 2,500 cP and a composition ratio of (Me₂SiO_{2/2})_{0.38}(PhSiO_{3/2})_{0.45}(CH₂═C₂═CH(Me)₂SiO_{1/2})_{0.17}. The amount of CH₂═CH—Si group in the silicone resin (B11) was 1.6 mmol/g. The amount of HO—Si group in the silicone resin (B11) was 1.8 mmol/g (3.0 mass %).

### Synthesis Example 12-1

<Synthesis of Silicone Resin (A12)>

Into a flask, 39.7 g of the silicone resin (I-1), 119 g of toluene, 39.7 g of methanol, 8.3 g of 1,1,3,3-tetramethyldisiloxane and 0.20 mL of 70% concentrated nitric acid were put. The resulting solution was stirred at room temperature. After a lapse of 4 hours, the thus-obtained reaction solution was put into a separatory funnel and subjected to extraction with 119 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (A12) was obtained as a colorless transparent viscous liquid.

The yield of the silicone resin (A12) was 42.5 g. The silicone resin (A12) had a mass-average molecular weight (Mw) of 1,900, a viscosity of 200 cP and a composition ratio of (Me₂SiO_{2/2})_{0.31}(PhSiO_{3/2})_{0.42}(H(Me)₂SiO_{1/2})_{0.27}. The amount of H—Si group in the silicone resin (A12) was 2.8 mmol/g. The amount of HO—Si group in the silicone resin (A12) was 2.0 mmol/g (3.4 mass %).

### Synthesis Example 12-2

<Synthesis of Silicone Resin (B11)>

Into a flask, 19.9 g of the silicone resin (I-1), 59.7 g of toluene, 19.9 g of methanol, 5.76 g of 1,3-divinyl-1,1,3,3-tetramethyldisiloxane and 1.98 mL of 70% concentrated nitric acid were put. The resulting solution was stirred at room temperature. After a lapse of 4 hours, the thus-obtained reaction solution was put into a separatory funnel and subjected to extraction with 59.7 g of water. The organic layer was recovered. The recovered organic layer was washed by repeating the above same operation four times. Then, toluene was distilled from the organic layer by an evaporator. The organic layer was distilled under reduced pressure by heating at 150° C. for 1 hour and further distilled twice under reduced temperature by heating at 170° C. for 1 hour. As a result, silicone resin (B12) was obtained as a colorless transparent viscous liquid.

The yield of the silicone resin (B12) was 20.6 g. The silicone resin (B11) had a mass-average molecular weight (Mw) of 1,800, a viscosity of 350 cP and a composition ratio of (Me₂SiO_{2/2})_{0.32}(PhSiO_{3/2})_{0.45}(CH₂CH₂═CH(Me)₂SiO_{1/2})_{0.23}. The amount of CH₂═CH—Si group in the silicone resin (B12) was 2.3 mmol/g. The amount of HO—Si group in the silicone resin (B12) was 2.1 mmol/g (3.6 mass %).

The composition ratio and physical properties (HO—Si group content amount, SiH or Si—CH═CH₂ group content amount, mass-average molecular weight, viscosity, refractive index and transparency) of the above-obtained silicone resins (A7) to (A12) and silicone resins (B7) to (B12) are indicated in TABLE 7. In TABLE 7, the abbreviation Vi refers to vinyl (CH₂═CH—).

TABLE 7

| | | Silicone resin | | | | | |
|---|---|---|---|---|---|---|---|
| | | (A7) | (A8) | (A9) | (A10) | (A11) | (A12) |
| Composition | (H—Me₂SiO_{1/2}) | 0.14 | 0.12 | 0.20 | 0.24. | 0.26 | 0.27 |
| ratio | (Me₂SiO_{2/2}) | 0.39 | 0.40 | 0.38 | 0.35 | 0.38 | 0.31 |
| | (PhSiO_{3/2}) | 0.47 | 0.48 | 0.42 | 0.41 | 0.36 | 0.42 |
| Amount of HO—Si group [mmol/g] | | 2.7 | 2.1 | 1.7 | 1.2 | 0.9 | 2.0 |
| Amount of H—Si group [mmol/g] | | 1.26 | 1.40 | 1.81 | 2.25 | 2.70 | 2.80 |
| Mass-average molecular weight [Mw] | | 6,100 | 5,600 | 5,800 | 5,700 | 5,700 | 1,900 |
| Viscosity [cP] | | 5,100 | 2,800 | 2,100 | 1,600 | 1,000 | 200 |
| Refractive index | | 1.5002 | 1.4962 | 1.4942 | 1.4910 | 1.4877 | 1.4879 |
| Transparency | Transmittance at 365 nm | 99% | 99% | 99% | 98% | 99% | 99% |
| | Transmittance at 405 nm | 99% | 100% | 99% | 99% | 99% | 99% |
| | | Silicone resin | | | | | |
| | | (B7) | (B8) | (B9) | (B10) | (B11) | (B12) |
| Composition | (Vi-Me₂SiO_{1/2}) | 0.09 | 0.17 | 0.13 | 0.15 | 0.17 | 0.23 |
| ratio | (Me₂SiO_{2/2}) | 0.42 | 0.39 | 0.48 | 0.40 | 0.38 | 0.32 |
| | (PhSiO_{3/2}) | 0.49 | 0.44 | 0.39 | 0.45 | 0.45 | 0.45 |
| Amount of HO—Si group [mmol/g] | | 2.6 | 2.3 | 2.2 | 1.9 | 1.8 | 2.1 |
| Amount of Vi-Si group [mmol/g] | | 0.87 | 1.05 | 1.17 | 1.43 | 1.60 | 2.30 |
| Mass-average molecular weight [Mw] | | 4,800 | 5,300 | 5,200 | 4,800 | 5,200 | 1,800 |
| Viscosity [cP] | | 6,500 | 5,000 | 3,900 | 3,000 | 2,500 | 350 |
| Refractive index | | 1.5039 | 1.5025 | 1.5012 | 1.4992 | 1.4977 | 1.4944 |
| Transparency | Transmittance at 365 nm | 98% | 98% | 98% | 97% | 97% | 98% |
| | Transmittance at 405 nm | 99% | 99% | 99% | 99% | 99% | 99% |

<Curable Silicone Resin Composition and Cured Product Thereof>

Compositions were prepared and cured into cured products. The viscosity of the respective compositions and the physical properties (hardness, adhesion, transparency, linear expansion coefficient, 5% weight reduction temperature and bonding strength) and appearance of the respective cured products were evaluated according to the same methods to those of Examples 1-6 and Comparative Examples 1 to 3. In the adhesion evaluation test, each of the cured products was tested not only for the adhesion to a 3528SMD type PPA resin package, but also for the adhesion to a 6050SMD type PPA resin package according to the following evaluation method. Further, the punching formability of the respective cured products was evaluated according to the following evaluation method. In each of Examples 7 to 12, the composition was prepared by mixing the silicone resin component (A) (any of the silicone resins (A7) to (A12)) and the silicone resin component (B) (any of the silicone resins (B7) to (B12)) at a mass ratio of 2:1 and further mixing a platinum catalyst as the component (C). As the platinum catalyst, a platinum-divinyltetramethyldisiloxane complex was used such that platinum was contained in an amount of 0.03 ppm in mass units relative to the total mass of the composition.

[Adhesion of Cured Product (6050SMD Type PPA Resin Package)]

The cured product, 9 samples for each composition, was formed by feeding the composition into a 6050SMD type PPA resin package (dimensions: 6.0 mm×5.0 mm×2.0 mm), heating the composition in the air at 90° C. for 1 hour and further heating the composition at 150° C. for 4 hours. Each of the samples was observed with an optical microscope. The sample was judged as “separated” when there occurred separation of the cured product from the package. When there occurred no separation of the cured product from the package, the sample was judged as “adhered”. The number of samples judged as “adhered”, out of 9 samples, was determined as the “number of passing grade samples”.

[Punching Formability]

The cured product was formed in a plate shape by feeding the composition into a mold (dimensions: 90 mm×90 mm×2 mm), heating the composition in the air at 90° C. for 1 hour and further heating the composition at 150° C. for 4 hours. The resulting plate-shaped cured product was punched into a dumbbell specimen of No. 8 according to JIS K 6251. The punching formability of the cured product was evaluated as “good” when the cured product was punched into the specimen without cracking and resin chipping. Otherwise, punching formability of the cured product was evaluated as “poor”.

The evaluation test results of the compositions and cured products of Examples 7 to 12 are indicated in TABLE 8.

TABLE 8

| | | Ex. 7 | Ex. 8 | Ex. 9 | Ex. 10 | Ex. 11 | Ex. 12 |
|---|---|---|---|---|---|---|---|
| Composition | Component (A) | (A7) | (A8) | (A9) | (A10) | (A11) | (A12) |
| | Component (B) | (B7) | (B8) | (B9) | (B10) | (B11) | (B12) |
| | Amount of platinum atom | 0.03 ppm | | | | | |
| | Viscosity | 5,000 | 4,200 | 3,300 | 2,500 | 2,000 | 200 |
| | Amount of Si—OH group | 2.6 | 2.2 | 1.9 | 1.4 | 1.2 | 2.0 |
| | [mmol/g] | | | | | | |
| Shore hardness | Shore A | A15 | A20 | A30 | A44 | A55 | A40 |

| | | | | | | | |
|---|---|---|---|---|---|---|---|
| Adhesion test | 3528 type | 16/16 | 16/16 | 16/16 | 15/16 | 14/16 | 3/16 |
| (Number of passing grade samples/ | 6050 type | 9/9 | 9/9 | 9/9 | 0/9 | 0/9 | 0/9 |
| total sample number) | | | | | | | |

| Transparency of | Transmittance at 365 nm | 90% | 90% | 90% | 91% | 91% | 89% |
|---|---|---|---|---|---|---|---|
| cured product | Transmittance at 405 nm | 91% | 90% | 91% | 91% | 92% | 90% |
| Heat resistant | Transmittance at 365 nm | 82% | 83% | 82% | 84% | 83% | 81% |
| transparency of | Transmittance at 405 nm | 88% | 89% | 89% | 88% | 88% | 88% |
| cured product | | | | | | | |
| Linear expansion coefficient [ppm] | | 274 | 252 | 244 | 241 | 235 | 248 |
| Heat resistance: T_{d5} [° C.] | | 346 | 336 | 388 | 353 | 367 | 335 |
| Bonding strength | Glass | cohesive | cohesive | cohesive | cohesive | cohesive | cohesive |
| [N] | | failure | failure | failure | failure | failure | failure |
| | Alumina | cohesive | cohesive | cohesive | cohesive | cohesive | cohesive |
| | | failure | failure | failure | failure | failure | failure |

| | | | | | | |
|---|---|---|---|---|---|---|
| Appearance of cured product | good | good | good | good | good | good |
| Punching formability | good | good | good | good | good | poor |

As indicated in TABLE 8, all of the cured products of Examples 7 to 12 had good heat resistant transparency. In the adhesion evaluation test, all of the cured product showed good adhesion to the 3528SMD type PPA resin package. The cured products of Examples 7 to 9, in each of which the resin component had a larger mass-average molecular weight and a larger content amount of Si—OH group than those of Examples 10 to 12, also showed good adhesion to the 6050SMD type PPA resin package of larger size than the 3528SMD type PPA resin package. In the punching formability evaluation test, the cured product of Example 12 in which the resin component had a small mass-average molecular weight was not punched into the specimen due to its insufficient resin strength. By contrast, the cured products of Examples 7 to 11, in each of which the resin component had a large mass-average molecular weight, were punched into the specimens with no problem.

### DESCRIPTION OF REFERENCE NUMERALS

1: Encapsulant
2: Optical semiconductor element
3: Bonding wire
4: Reflector member
5: Leadframe
6: Optical semiconductor substrate
10: Optical semiconductor device

1. A curable silicone resin composition comprising at least the following components:
(A) a silicone resin having a hydrogen atom bonded to silicon atom (as SiH group) as represented by the following formula [1];
(B) a silicone resin having a vinyl group bonded to silicon atom (as Si—CH═CH₂ group) as represented by the following formula [2]; and
(C) a platinum catalyst,
wherein the total amount of silanol (Si—OH) group in the components (A) and (B) is 0.5 to 5.0 mmol/g; and
wherein the amount of platinum in the component (C) relative to the total mass of the components (A), (B) and (C) is 0.003 to 3.0 ppm in mass units,
(H—SiR¹₂O_{1/2})ₐ(SiR²₂O_{2/2})_{b}(R³SiO_{3/2})_{c}(SiO_{4/2})_{d} [1]
where R¹ is each independently a C₁-C₃ alkyl group; two R¹ may be of the same kind or different kinds; R² is each independently a C₁-C₃ alkyl group; two R² may be of the same kind or different kinds; R³ is a C₁-C₃ alkyl group or C₆-C₁₀ aromatic hydrocarbon group; a, b and c are each independently a number greater than 0 and smaller than 1; d is a number greater than or equal to 0 and smaller than 1; a, b, c and d satisfy the condition of a+b+c+d=1; and each of oxygen atoms in structural units (SiR²₂O_{2/2}), (R³SiO_{3/2}) and (SiO_{4/2}) is a siloxane bond-forming oxygen atom or a silanol group-forming oxygen atom;
(CH₂═CH—SiR⁴₂O_{1/2})ₑ(SiR⁵₂O_{2/2})_{f}(R⁶SiO_{3/2})_{g}(SiO_{4/2})ₕ [2]
where R⁴ is each independently a C₁-C₃ alkyl group; two R⁴ may be of the same kind or different kinds; R⁵ is each independently a C₁-C₃ alkyl group; two R⁵ may be of the same kind or different kinds; R⁶ is a C₁-C₃ alkyl group or C₆-C₁₀ aromatic hydrocarbon group; e, f and g are each independently a number greater than 0 and smaller than 1; h is a number greater than or equal to 0 and smaller than 1; e, f g and h satisfy the condition of e+f+g+h=1; and each of oxygen atoms in structural units (SiR⁵₂O_{2/2}), (R⁶SiO_{3/2}) and (SiO_{4/2}) is a siloxane bond-forming oxygen atom or a silanol group-forming oxygen atom.

2. The curable silicone resin composition according to claim 1,
wherein the ratio of a mole number of the hydrogen atom bonded to the silicon atom in the component (A) to a mole number of the vinyl group bonded to the silicon atom in the component (B) is in a range of 0.8:0.2 to 0.5:0.5.

3. The curable silicone resin composition according to claim 1,
wherein, in the component (A), a, b, c and d satisfy the condition of a:b:c:d=0.05 to 0.40:0.10 to 0.80:0.10 to 0.80:0 to 0.70; and
wherein, in the component (B), e, f, g and h satisfy the condition of e:f:g:h=0.05 to 0.40:0.10 to 0.80:0.10 to 0.80:0 to 0.70.

4. The curable silicone resin composition according to claim 1,
wherein, in the component (A), a, b, c and d satisfy the condition of a:b:c:d=0.20 to 0.40:0.10 to 0.40:0.30 to 0.60:0.10 to 0.30; and
wherein, in the component (B), e, f, g and h satisfy the condition of e:f:g:h=0.20 to 0.40:0.10 to 0.40:0.30 to 0.60:0.10 to 0.30.

5. The curable silicone resin composition according to claim 1,
wherein, in the component (A), a, b, c and d satisfy the condition of d=0 and a:b:c=0.05 to 0.40:0.10 to 0.80:0.10 to 0.80; and
wherein, in the component (B), e, f g and h satisfy the condition of h=0 and e:f:g=0.05 to 0.40:0.10 to 0.80:0.10 to 0.80.

6. The curable silicone resin composition according to claim 1, further comprising a curing retardant.

7. The curable silicone resin composition according to claim 1, further comprising an antioxidant or a light stabilizer.

8. The curable silicone resin composition according to claim 1, further comprising one or more kinds selected from the group consisting of a bonding aid, a phosphor and an inorganic particulate material.

9. The curable silicone resin composition according to claim 1, further comprising one or more kinds selected from the group consisting of a mold releasing agent, a resin modifying agent, a coloring agent, a diluent, an antimicrobial agent, a fungicide, a leveling agent and an anti-sagging agent.

10. A cured product formed by curing the curable silicone resin composition according to claim 1.

11. An encapsulant comprising a cured product of the curable silicone resin composition according to claim 1.

12. A method for forming a cured product by curing the curable silicone resin composition according to claim 1, comprising heating the curable silicone resin composition at 45° C. to 300° C.

13. An optical semiconductor device comprising an optical semiconductor element encapsulated by a cured product of the curable silicone resin composition according to claim 1.

14. A semiconductor bonding material comprising a cured product of the curable silicone resin composition according to claim 1.

15. An optical semiconductor device comprising the semiconductor bonding material according to claim 14.
